(19) United States
(12) Patent Application Publication
(10) Pub. No.: US 2021/0073610 A1
(43) Pub. Date: Mar. 11, 2021

(54) THIN FILM MANUFACTURING APPARATUS AND THIN FILM MANUFACTURING APPARATUS USING NEURAL NETWORK

(71) Applicant: SEMICONDUCTOR ENERGY LABORATORY CO., LTD., Atsugi-shi, Kanagawa-ken (JP)

(72) Inventors: Kazutaka KURIKI, Ebina, Kanagawa (JP); Sachiaki TEZUKA, Isehara, Kanagawa (JP); Kouhei TOYOTAKA, Atsugi, Kanagawa (JP)

(21) Appl. No.: 16/772,281

(22) PCT Filed: Dec. 18, 2018
(86) PCT No.: PCT/IB2018/060211

§ 371 Date: Jun. 12, 2020

(30) Foreign Application Priority Data
Dec. 27, 2017 (JP) 2017-251057

(51) Int. Cl. G06N 3/02; H01L 21/02; H05H 1/46

(52) U.S. Cl. CPC G06N 3/02; H05H 1/46; H01L 21/02532

(57) ABSTRACT

A thin film manufacturing apparatus capable of forming thin films with high uniformity is provided. A thin film manufacturing apparatus capable of controlling various kinds of set conditions during thin film formation is provided. The thin film manufacturing apparatus includes a treatment chamber, a gas supply means, an evacuation means, an electric power supply means, an arithmetic portion, and a control device; the gas supply means supplies gas into the treatment chamber; the evacuation means adjusts a pressure in the treatment chamber; the electric power supply means applies voltage between electrodes provided in the treatment chamber; the arithmetic portion has a function of performing detection of an abnormal state and inference with the use of a neural network during thin film formation; and the control device controls various kinds of set conditions in accordance with results of the detection and the inference during the thin film formation.

### TECHNICAL FIELD

One embodiment of the present invention relates to a thin film manufacturing apparatus used for thin film formation and element fabrication. One embodiment of the present invention relates to a thin film manufacturing apparatus used for thin film formation and element fabrication utilizing plasma, One embodiment of the present invention relates to a thin film manufacturing apparatus that uses a neural network and is used for thin film formation and element fabrication utilizing plasma. One embodiment of the present invention relates to a control system using a neural network.

In this specification and the like, a semiconductor device generally means a device that can function by utilizing semiconductor characteristics. A display device, a light-emitting device, a memory device, an electro-optical device, a power storage device, a semiconductor circuit, and an electronic device include the semiconductor device in some cases.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter.

### BACKGROUND ART

In recent years, machine learning techniques such as an artificial neural network (hereinafter referred to as a neural network) have been actively developed. Patent Document 1 discloses an example in which a thin film manufacturing apparatus is provided with a neural network.

In recent years, transistors using oxide semiconductors or metal oxides in their channel formation regions (hereinafter, referred to as OS transistors) have attracted attention. The off-state current of an OS transistor is extremely low. Applications that employ OS transistors to utilize their extremely low off-state currents have been proposed. For example, Patent Document 2 discloses an example in which an OS transistor is used for learning in a neural network.

### REFERENCE

### Patent Document

[Patent Document 1] Japanese Published Patent Application No. H5-190457

### [Patent Document 2] Japanese Published Patent Application No. 2016-219011

### SUMMARY OF THE INVENTION

### Problems to be Solved by the Invention

In the case of forming thin films with a thin film manufacturing apparatus, it is important to control the film quality and film thickness of the thin films formed. However, even when thin films are formed while one or more set conditions under which the thin films are formed (which are sometimes referred to as various kinds of set conditions or various kinds of deposition conditions in this specification) are kept constant, the film quality and film thickness of the thin films formed are sometimes different from the flint quality and film thickness assumed from the various kinds of set conditions.

In view of the above, an object of one embodiment of the present invention is to provide a thin film manufacturing apparatus capable of forming thin films with high uniformity. Another object of one embodiment of the present invention is to provide a thin film manufacturing apparatus with high productivity. Another object of one embodiment of the present invention is to provide a thin film manufacturing apparatus using a neural network capable of controlling various kinds of set conditions during thin film formation.

Note that the descriptions of these objects do not disturb the existence of other objects. One embodiment of the present invention does not have to achieve all the objects. Objects other than these will be apparent from the descriptions of the specification, the drawings, the claims, and the like, and can be derived from the descriptions of the specification, the drawings, the claims, and the like.

### Means for Solving the Problems

One embodiment of the present invention is a thin film manufacturing apparatus which includes a treatment chamber, a gas supply means, an evacuation means, an electric power supply means, an arithmetic portion, and a control device and in which the gas supply means supplies gas into the treatment chamber, the evacuation means adjusts a pressure in the treatment chamber, the electric power supply means applies voltage between electrodes provided in the treatment chamber, the arithmetic portion has a function of performing detection of an abnormal state and inference with the use of a neural network during thin film formation, and the control device controls various kinds of set conditions in accordance with results of the detection and the inference during the thin film formation.

One embodiment of the present invention is a thin film manufacturing apparatus which includes a treatment chamber, a gas supply means, an evacuation means, an electric power supply means, a matching box, an arithmetic portion, and a control device and in which the gas supply means supplies gas into the treatment chamber, the evacuation means adjusts a pressure in the treatment chamber, the electric power supply means applies voltage between electrodes provided in the treatment chamber using a high-frequency power source, the matching box has a function of inducing AC power effectively and a function of acquiring data during thin film formation, the arithmetic portion has a function of performing detection of an abnormal state and inference with the use of a neural network during the thin film formation, and the control device controls various kinds of set conditions in accordance with results of the detection and the inference during the thin film formation.

One embodiment of the present invention is a thin film manufacturing apparatus which includes a treatment chamber, a gas supply means, an evacuation means, an electric power supply means, a matching box, an electrode interval adjustment means, a temperature adjustment means, an arithmetic portion, and a control device and in which the gas supply means supplies gas into the treatment chamber, the evacuation means adjusts a pressure in the treatment chamber, the electric power supply means applies voltage between two electrodes provided in the treatment chamber using a high-frequency power source, the matching box has a function of inducing AC power effectively and a function of acquiring data during thin film formation, the electrode interval adjustment means adjusts an interval between the two electrodes provided in the treatment chamber, the temperature adjustment means adjusts a temperature in the treatment chamber, the arithmetic portion has a function of performing detection of an abnormal state and inference with the use of a neural network during the thin film formation, and the control device controls various kinds of set conditions in accordance with results of the detection and the inference during the thin film formation.

In the above, it is preferable that the neural network finish learning for performing the detection and learning for performing the inference in advance on the basis of the various kinds of set conditions accumulated in a certain period and the data acquired during the thin film formation under the various kinds of set conditions.

In the above, it is preferable that the arithmetic portion include a memory, the memory include a transistor and a capacitor, and the transistor include a metal oxide in a channel formation region.

In the above, it is preferable that the arithmetic portion include a semiconductor device, the semiconductor device have a function of performing operation of the neural network, the semiconductor device include a memory cell, and a transistor including a metal oxide in a channel formation region be used in the memory cell.

In the above, it is preferable that the various kinds of set conditions be one or more selected from a kind and a flow rate or a flow rate ratio of the gas, the pressure in the treatment chamber, the voltage applied between the electrodes, a distance between the electrodes, and a substrate temperature, and the data be one or both of a difference between the maximum voltage and the minimum voltage of AC voltage (Vpp) and a potential difference between a coil and an earth (Vdc).

In the above, it is preferable that a deposition treatment using a plasma CVD method can be performed in the treatment chamber.

### Effect of the Invention

According to one embodiment of the present invention, a thin film manufacturing apparatus capable of forming thin films with high uniformity can be provided. According to one embodiment of the present invention, a thin film manufacturing apparatus with high productivity can be provided. According to one embodiment of the present invention, a thin film manufacturing apparatus using a neural network capable of controlling various kinds of set conditions during thin film formation can be provided.

Note that the descriptions of the effects do not disturb the existence of other effects. Note that one embodiment of the present invention does not need to have all these effects. Effects other than these will be apparent from the descriptions of the specification, the drawings, the claims, and the like and effects other than these can be derived from the descriptions of the specification, the drawings, the claims, and the like.

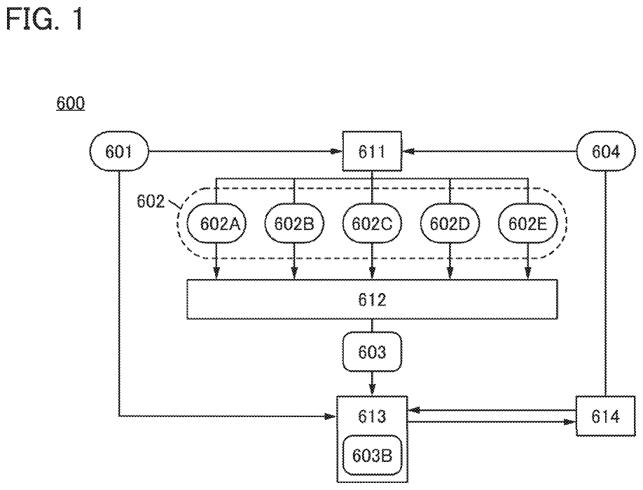

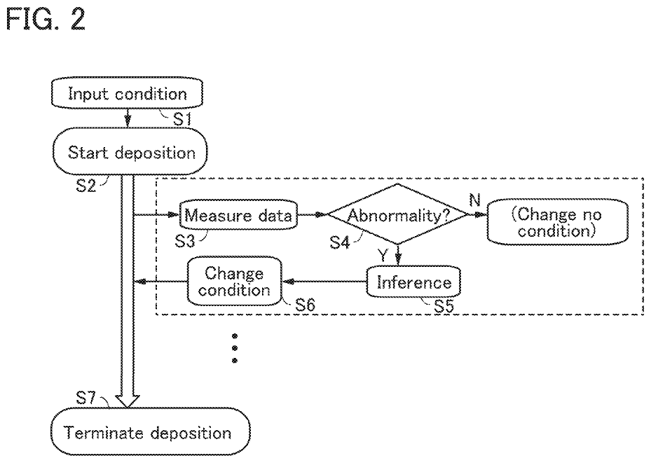

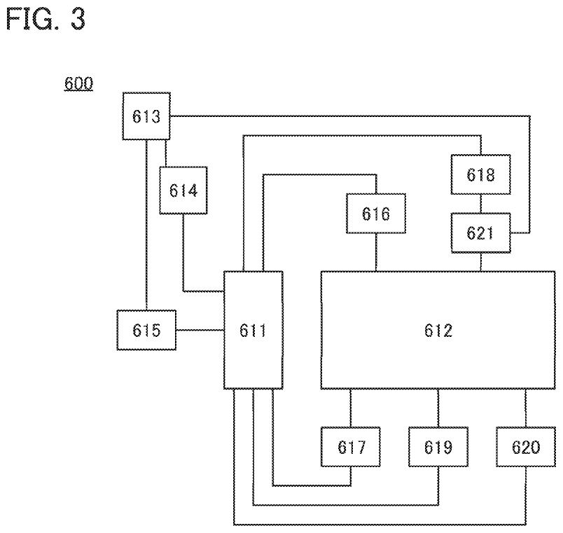

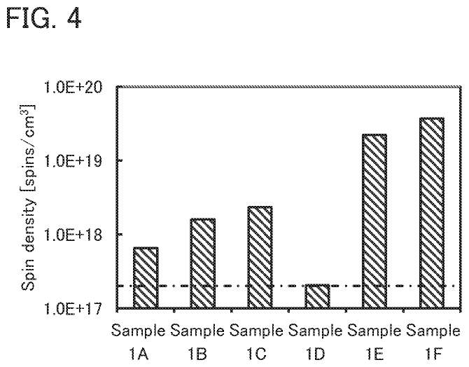

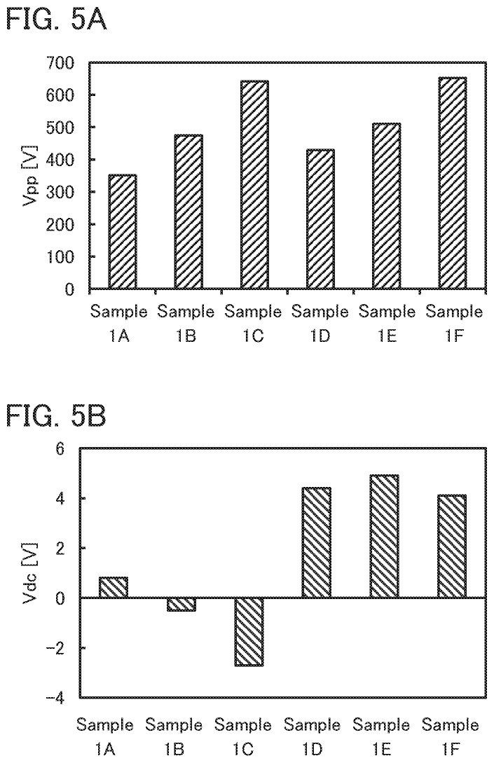

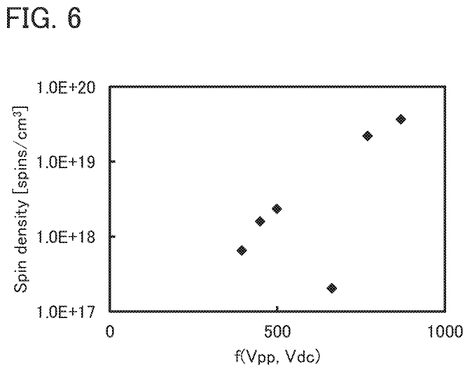

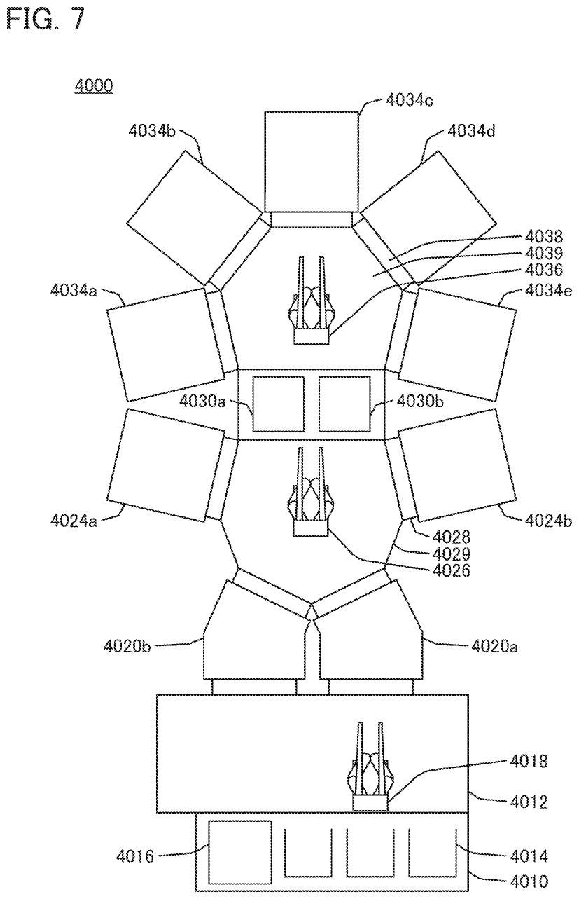

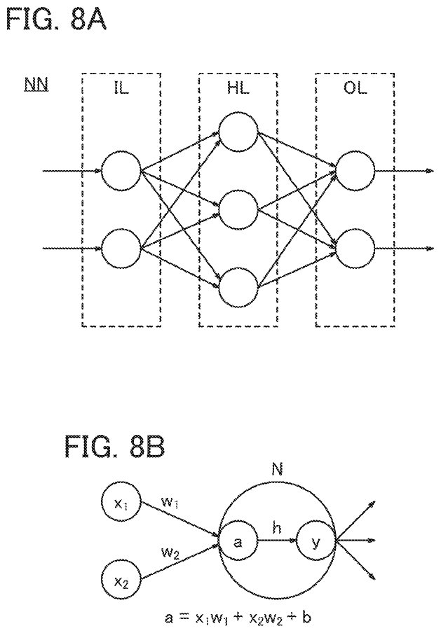

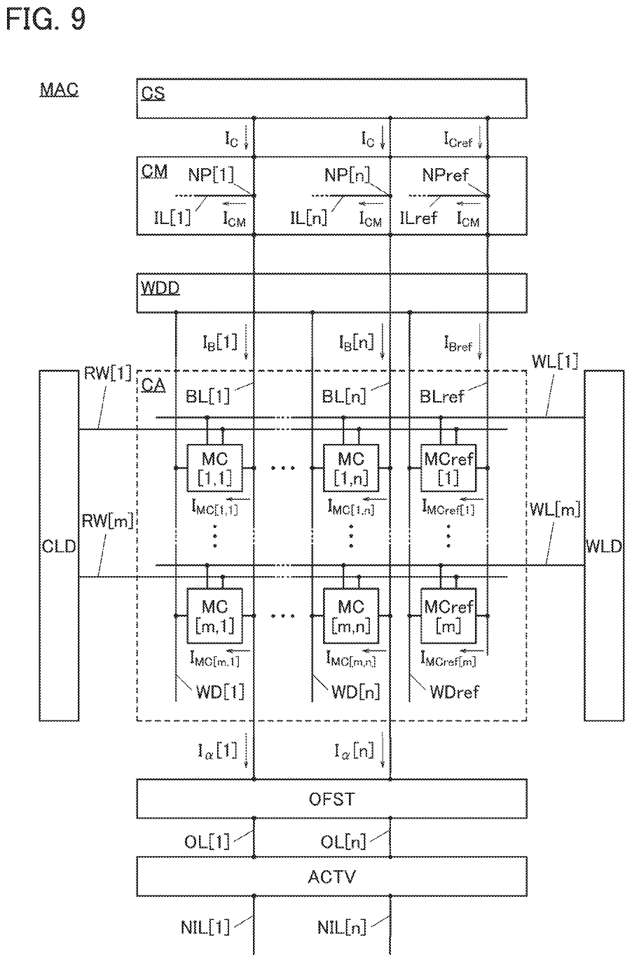

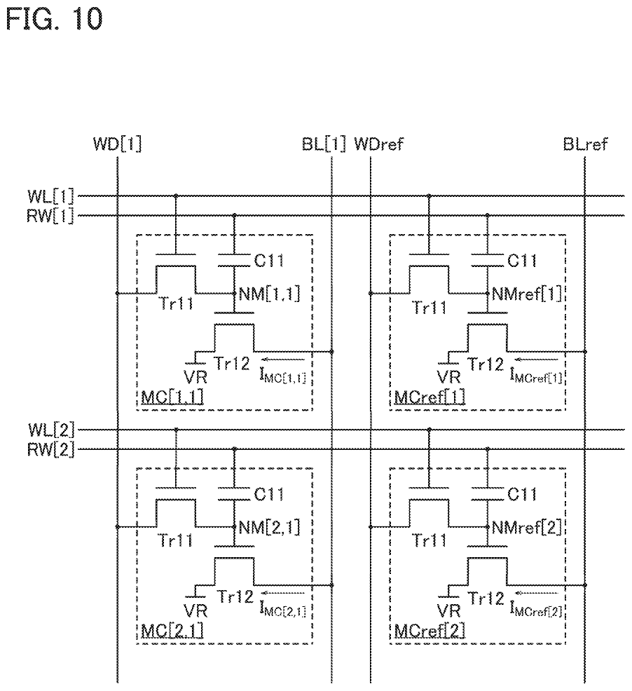

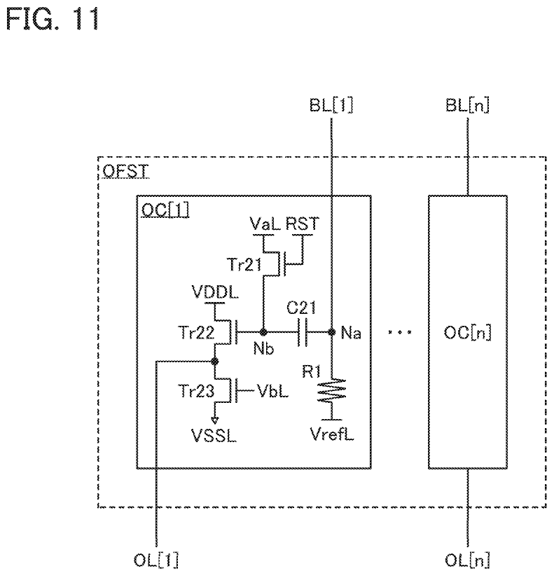

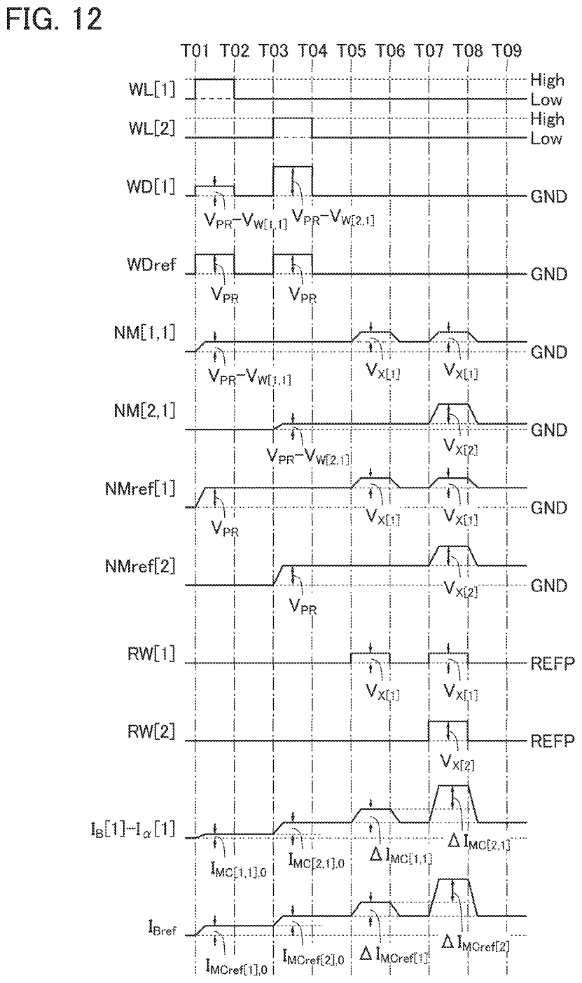

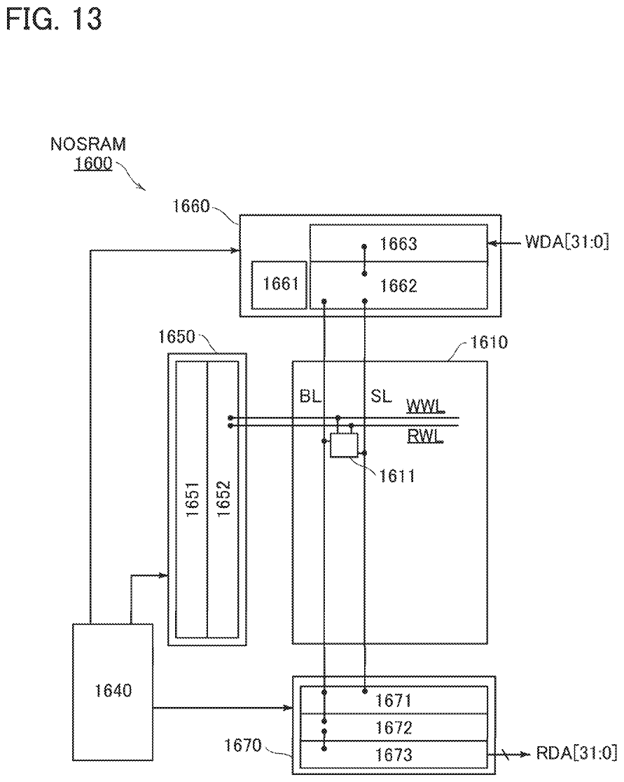

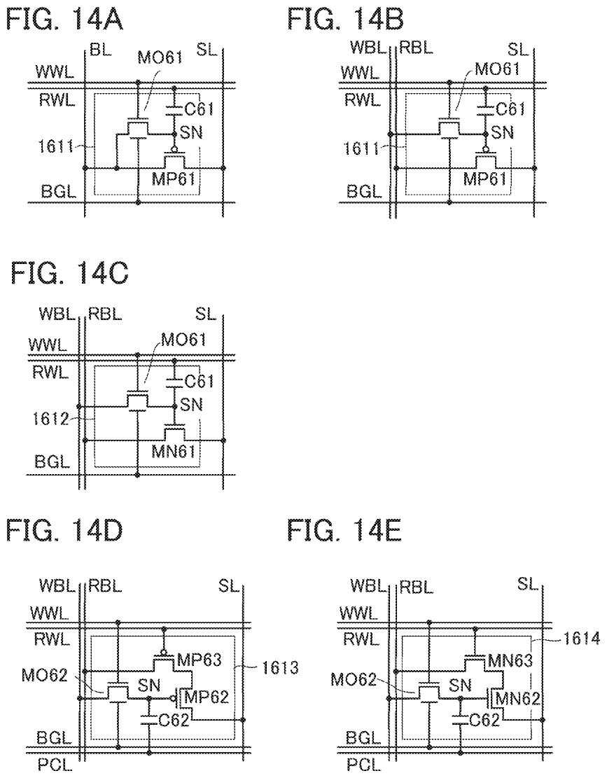

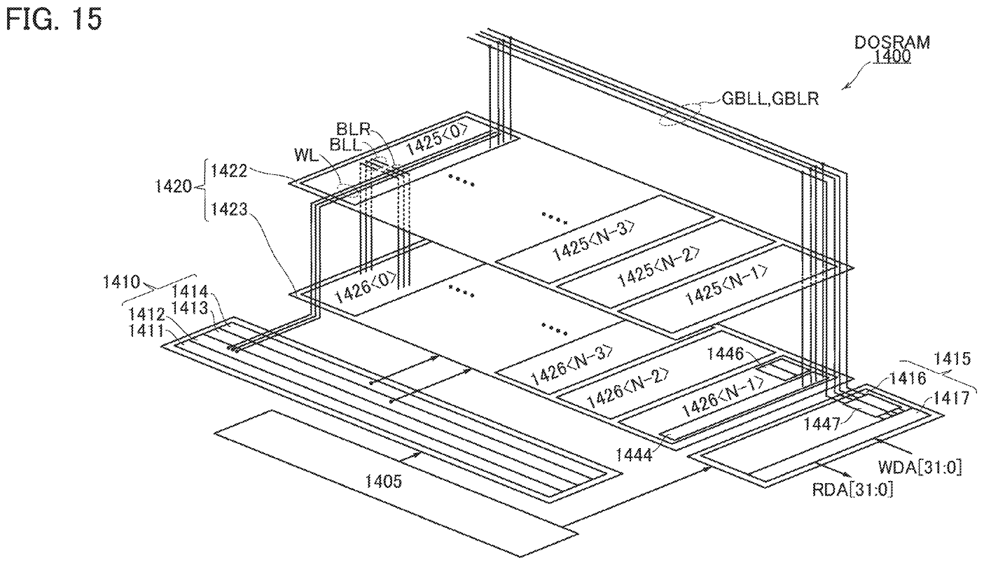

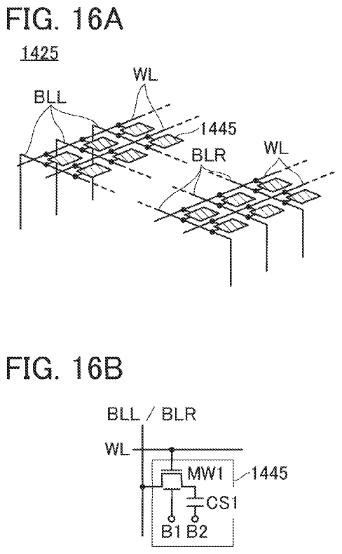

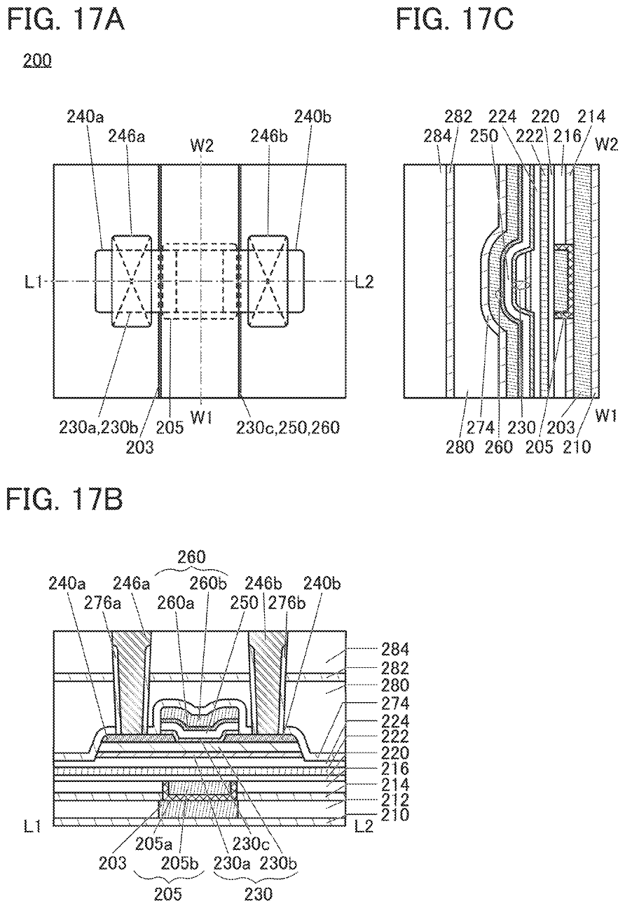

### BRIEF DESCRIPTION OF THE DRAWINGS

[FIG. 1] A diagram illustrating an example of transmission and reception of data in a plasma CVD apparatus of one embodiment of the present invention.

[FIG. 2] A flowchart illustrating a method for controlling various kinds of set conditions in a plasma CVD apparatus of one embodiment of the present invention,

[FIG. 3] A block diagram illustrating a structure example of a plasma CVD apparatus of one embodiment of the present invention.

[FIG. 4] A diagram showing spin densities of samples.

[FIG. 5] Diagrams showing values of Vpp and Vdc under various kinds of set conditions.

[FIG. 6] A diagram showing spin densities of samples with respect to a function of Vpp and Vdc.

[FIG. 7] A top view explaining an apparatus for manufacturing a semiconductor device of one embodiment of the present invention.

[FIG. 8] Diagrams illustrating a configuration example of a neural network.

[FIG. 9] A diagram illustrating a configuration example of a semiconductor device.

[FIG. 10] A diagram illustrating a configuration example of memory cells.

[FIG. 11] A diagram illustrating a configuration example of an offset circuit.

[FIG. 12] A timing chart.

[FIG. 13] A block diagram illustrating a configuration example of a memory device of one embodiment of the present invention.

[FIG. 14] Circuit diagrams illustrating configuration examples of a memory device of one embodiment of the present invention.

[FIG. 15] A block diagram illustrating a configuration example of a memory device of one embodiment of the present invention.

[FIG. 16] A block diagram and a circuit diagram illustrating a configuration example of a memory device of one embodiment of the present invention.

[FIG. 17] A top view and cross-sectional views illustrating a structure example of a transistor.

### MODE FOR CARRYING OUT THE INVENTION

Hereinafter, embodiments will be described with reference to the drawings. Note that the embodiments can be implemented with many different modes, and it will be readily appreciated by those skilled in the art that modes and details thereof can be changed in various ways without departing from the spirit and scope thereof Therefore, the present invention should not be interpreted as being limited to the descriptions of the embodiments below.

In the drawings, the size, the layer thickness, or the region is exaggerated for clarity in some cases. Therefore, they are not limited to the illustrated scale. The drawings are schematic views showing ideal examples, and embodiments of the present invention are not limited to shapes, values, and the like shown in the drawings.

In this specification and the like, a thin film manufacturing apparatus generally means a processing apparatus necessary for manufacture of thin films. A vacuum deposition apparatus (typically, a sputtering apparatus, a CVD apparatus, or the like), a plasma apparatus, an etching apparatus, an asking apparatus, a cleaning apparatus, and an apparatus that combines these can be referred to as one mode of a thin film manufacturing apparatus.

In this specification, a neural network refers to a general model that is modeled on a biological neural network, determines the connection strength of neurons by learning, and has the capability of solving problems. A neural network includes an input layer, an intermediate layer (also referred to as a hidden layer), and an output layer.

In describing a neural network in this specification, to determine a connection strength of neurons (also referred to as a weight coefficient) from existing information is sometimes referred to as “learning”.

Moreover, in this specification, to draw a new conclusion from a neural network formed using a connection strength obtained by learning is sometimes referred to as “inference”.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a channel formation region of a transistor, the metal oxide is called an oxide semiconductor in some cases. That is, an OS transistor can also be called a transistor including a metal oxide or an oxide semiconductor.

Note that in this specification and the like, a metal oxide containing nitrogen is also collectively referred to as a metal oxide in some cases. A metal oxide containing nitrogen may be referred to as a metal oxynitride.

### Embodiment 1

This embodiment describes a thin film manufacturing apparatus that has a function of adjusting various kinds of set conditions by performing inference by a neural network in the case where an abnormal state is detected during thin film formation.

In manufacture of semiconductor elements, for example, a thin film formation technique and an element fabrication technique are used. As examples of a thin film formation method, a sputtering method, a chemical vapor deposition (CVD) method, a molecular beam epitaxy (MBE) method, a pulsed laser deposition (PLD) method, an atomic layer deposition (ALD) method, and the like can be given.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on gas to be used which is a material of thin films (also referred to as a source gas).

A thin film manufacturing apparatus includes a treatment chamber (also referred to as a reaction chamber), a gas supply means, an evacuation means, an electric power supply means, and the like. The gas supply means supplies gas to the treatment chamber. The evacuation means adjusts the pressure in the treatment chamber. The electric power supply means applies voltage between electrodes provided in the treatment chamber. Thin film formation is performed by adjusting one or more set conditions at the time when a thin film is formed (also simply referred to as various kinds of set conditions or various kinds of deposition conditions), such as the kind and flow rate or flow rate ratio of the gas supplied, the pressure in the treatment chamber, and the voltage applied between the electrodes.

Even when a thin film is formed with the above various kinds of set conditions kept constant, the film quality and film thickness of the thin films formed are sometimes different from the film quality and film thickness assumed from the above various kinds of set conditions. This is probably because the conditions affecting the film quality and deposition rate of a thin film change unexpectedly during thin film formation. In addition, even when various kinds of set conditions are the same, the film quality and film thickness of thin films might differ before and after maintenance of the thin film manufacturing apparatus or cleaning of the treatment chamber of the thin film manufacturing apparatus.

In view of this, a thin film manufacturing apparatus of one embodiment of the present invention includes an arithmetic portion and a control device in addition to a treatment chamber, a gas supply means, an evacuation means, an electric power supply means, and the like. Furthermore, the arithmetic portion has a function of performing inference using a neural network. Accordingly, the thin film manufacturing apparatus of one embodiment of the present invention has a function of constantly measuring data other than various kinds of set conditions during thin film formation to monitor whether an abnormal state is generated in the data. In addition, the thin film manufacturing apparatus of one embodiment of the present invention has a function of adjusting various kinds of set conditions by performing inference with the neural network when an abnormal state is detected.

With the use of a thin film manufacturing apparatus of one embodiment of the present invention, the film quality and film thickness of thin films can be uniform. Furthermore, adjusting various kinds of set conditions during thin film formation makes it possible to form thin films without suspension of the thin film formation process. Since thin films can be formed without suspension of the thin film formation process, the productivity can be high.

### <Plasma CVD Apparatus>

A thin film manufacturing apparatus of one embodiment of the present invention will be described below with reference to FIG. 1 to FIG. 5, using a thin film manufacturing apparatus employing a plasma CVD method (which is referred to as a plasma CVD apparatus) as an example.

Deposition using a CVD method allows a high deposition rate and a large treatment area and is thus suitable for deposition on a large-size substrate. Specifically, thin films can be formed at lower temperatures by a plasma CVD method than by a thermal CVD method. When a plasma CVD method is used for deposition, damage to thin films and diffusion of atoms between layers due to heat can be inhibited.

When a thin film is formed using a plasma CVD apparatus with various kinds of deposition conditions kept constant, the film quality and film thickness of the thin films formed are sometimes different from the film quality and film thickness assumed from the various kinds of conditions. This is probably because the conditions affecting the film quality and deposition rate of a thin film change unexpectedly during deposition. In addition, even when various kinds of deposition conditions are the same, the film quality and film thickness of thin films formed might differ from the film quality and film thickness assumed from the various kinds of deposition conditions before and after maintenance of the plasma CVD apparatus or cleaning of a treatment chamber of the plasma CVD apparatus.

In view of the above, understanding the principle of thin film formation by a plasma CVD method and controlling various kinds of deposition conditions are important for uniform film quality and film thickness of thin films.

However, the principle of thin film formation by a plasma CVD method has not been fully elucidated. There are a plurality of deposition conditions, such as the kind and flow rate or flow rate ratio of the gas supplied to a treatment chamber, the pressure in the treatment chamber, the application voltage between electrodes (which is sometimes called deposition power in the case of a plasma CVD apparatus), the distance between the electrodes, and substrate temperature. Accordingly, the correlation between the various kinds of deposition conditions and the film quality and film thickness of thin films is not easily found. In addition, data other than the various kinds of deposition conditions needs to be acquired because the conditions that affect the film quality and deposition rate of thin films change in spite of the fact that the various kinds of deposition conditions are kept constant.

For example, data other than the various kinds of deposition conditions is measured during deposition to monitor the thin film formation process in some cases. Examples of the data include Vpp and Vdc. Vpp refers to a difference between the maximum voltage and the minimum voltage of AC voltage. Vdc refers to a potential difference between a coil and an earth in this specification. A sensor for measuring Vpp and Vdc is mounted in a matching box for the electric power supply means that is provided with a high-frequency power source. Note that the matching box has a function of inducing high-frequency power effectively into the treatment chamber.

The above-mentioned Vpp and Vdc are known to affect the film quality and deposition rate of a thin film. Furthermore, various kinds of deposition conditions are known to contribute to Vpp and Vdc. Thus, it is assumed that the film quality and film thickness change by a change in one or both of Vpp and Vdc during deposition. Note that the correlation between the film quality and Vpp and Vdc and that between various kinds of deposition conditions and Vpp and Vdc will be described later.

In view of the above, the plasma CVD apparatus of one embodiment of the present invention has a function of constantly measuring Vpp and Vdc during deposition to monitor whether an abnormal state is generated in one or both of Vpp and Vdc. Furthermore, the plasma CVD apparatus of one embodiment of the present invention has a function of performing inference of various kinds of deposition conditions with the neural network and adjusting various kinds of deposition conditions on the basis of the inference result when an abnormal state is detected.

With the use of the plasma CVD apparatus of one embodiment of the present invention, the film quality and film thickness of thin films can be uniform. In addition, adjusting various kinds of deposition conditions during deposition makes it possible to form thin films without suspension of the thin film formation process. Since thin films can be formed without suspension of the thin film formation process, the productivity can be high.

Examples of a thin film that can be formed with the plasma CVD apparatus of one embodiment of the present invention include insulating films typified by a silicon oxide film, a silicon oxynitride film, and a silicon nitride film, semiconductor films typified by a microcrystalline silicon film and an amorphous silicon film, diamond-like carbon (DLC) excellent in biological compatibility, abrasion resistance, and the like, and furthermore, various kinds of thin films used in semiconductor devices, photoelectric conversion devices, and the like.

Here, DLC is a film that has a SP3 bond as a bond between carbons in terms of short range order and has an amorphous structure from a macroscopic aspect.

### [Example of Transmission and Reception of Data]

An example of transmission and reception of data in a plasma CVD apparatus of one embodiment of the present invention will be described with reference to FIG. 1. FIG. 1 illustrates the flow of data that is transmitted and received between devices included in a plasma CVD apparatus 600. The plasma CVD apparatus 600 includes a control device 611, a treatment chamber 612, an arithmetic portion 613, and a controller IC 614. In addition, as data transmitted and received, there are various kinds of initial deposition conditions 601, various kinds of deposition conditions 602, a measurement value 603, and various kinds of deposition conditions 604.

First of all, the various kinds of initial deposition conditions 601 are transmitted to the control device 611 and the arithmetic portion 613.

When the control device 611 receives the various kinds of initial deposition conditions 601, the various kinds of deposition conditions 602 are generated. There are a plurality of deposition conditions, such as the kind and flow rate or flow rate ratio of the gas supplied to a treatment chamber, the pressure in the treatment chamber, the deposition power, the distance between the electrodes, and substrate temperature. In this embodiment, an example is described in which the various kinds of deposition conditions 602 are gas 602A, a pressure 602B in a treatment chamber, deposition power 602C, a distance between electrodes 602D, and substrate temperature 602E. Note that the gas 602A means the kind and flow rate or flow rate ratio of the gas supplied to the treatment chamber. The various kinds of deposition conditions 602 generated are transmitted to the treatment chamber 612 or several means connected to, for example, electrodes provided in the treatment chamber 612. The several means receive the various kinds of deposition conditions 602, and a thin film starts to be formed in the treatment chamber 612 in accordance with the various kinds of deposition conditions 602. Note that the several means will be described later.

Since the start of thin film formation in the treatment chamber 612, the measurement value 603 is acquired at regular intervals of time. Examples of the measurement value 603 include Vpp and Vdc. Note that in the case where the measurement value 603 is Vpp and Vdc, the measurement value 603 is acquired with a sensor provided in a matching box. Note that the matching box is electrically connected to an electrode provided in the treatment chamber 612. The measurement value 603 acquired is transmitted to the arithmetic portion 613.

The arithmetic portion 613 includes a memory (not shown), and a region for first data and a region for second data are secured in the memory. The various kinds of initial deposition conditions 601 received by the arithmetic portion 613 are stored in the region for the first data. The measurement value 603 received by the arithmetic portion 613 is stored in the region for the second data.

The arithmetic portion 613 can perform learning and inference by a neural network with the use of the data stored in the above memory. The learning and inference by a neural network will be described later. Note that a weight coefficient used for the neural network of the arithmetic portion 613 may be a weight coefficient determined by an external device (not shown). For example, a weight coefficient determined by a neural network of an external device is stored in the neural network of the arithmetic portion 613, in which case the neural network of the arithmetic portion 613 can perform the same operation as the neural network that has performed learning.

The controller IC 614 has a function of controlling the timing of the inference performed by the arithmetic portion 613 and a function of controlling the control device 611. The controller IC 614 transmits an instruction for performing inference to the arithmetic portion 613. When the arithmetic portion 613 receives the instruction, inference is performed with the neural network of the arithmetic portion 613. For example, when inference is performed with the use of the data (the various kinds of initial deposition conditions 601) stored in the region for the first data, the result of inferring the measurement value (an output value 603B) is generated.

After the generation of the output value 603B, the data (the measurement value 603) stored in the region for the second data and the output value 6033 are compared in the arithmetic portion 613. On the basis of the comparison result, whether an abnormal state is generated is determined. An abnormal state refers to the case where a state where the measurement value 603 is constant (a normal state) changes to a different state and the amount of change from the normal state to the different state is large. For example, an abnormal state refers to the case where a state in which a difference between the measurement value 603 and the output value 6033 is large continues. Note that whether an abnormal state is generated may be determined by the neural network of the arithmetic portion 613 or by the controller IC 614.

Inference is performed with the use of the data (the various kinds of initial deposition conditions 601) stored in the region for the first data to generate the result of the inference of the measurement value in this embodiment; however, the present invention is not limited thereto. For example, inference is performed using the neural network from the data (the measurement value 603) stored in the region for the second data to generate the result of inference of various kinds of deposition conditions. Then, the various kinds of deposition conditions generated by the inference and the data (the various kinds of initial deposition conditions 601) stored in the region for the first data may be compared to determine whether an abnormal state is generated.

In the case where it is determined that an abnormal state is not generated, an instruction for changing the various kinds of deposition conditions is not transmitted from the controller IC 614 to the control device 611. Accordingly, thin film formation continues without a change in the various kinds of deposition conditions 602.

In contrast, in the case where it is determined that an abnormal state is generated, the neural network performs learning such that the output value 603B agrees with the data (the measurement value 603) stored in the region for the second data. When inference is performed with the neural network that has performed learning, the various kinds of deposition conditions 604 are newly generated.

After that, an instruction for changing various kinds of deposition conditions is transmitted from the controller IC 614 to the control device 611. Then, the various kinds of deposition conditions 604 are transmitted from the arithmetic portion 613 to the control device 611 through the controller IC 614. Note that the various kinds of deposition conditions 604 may be transmitted from the arithmetic portion 613 to the control device 611 without through the controller IC 614. In addition, the various kinds of deposition conditions 604 are stored in the region for the first data in the memory of the arithmetic portion 613. On reception of the instruction and the various kinds of deposition conditions 604 by the control device 611, the various kinds of deposition conditions 602 are generated again on the basis of the various kinds of deposition conditions 604. Thin film formation continues on the basis of the various kinds of deposition conditions 602 generated again.

As described above, when the measurement value 603 is kept constant, the film quality and film thickness of thin films can be uniform. In addition, adjusting various kinds of deposition conditions during deposition makes it possible to form thin films without suspension of the thin film formation process. Since thin films can be formed without suspension of the thin film formation process, the productivity can be high.

### [Flowchart Illustrating Method for Controlling Various Kinds of Deposition Conditions]

A method for controlling various kinds of deposition conditions will be described below with reference to FIG. 2. FIG. 2 is a flowchart illustrating adjustment of various kinds of deposition conditions.

First, various kinds of initial deposition conditions are input to a control device (Step S1). Then, thin film formation is started on the basis of the various kinds of deposition conditions input to the control device (Step S2).

After the thin film formation is started, data (Vpp, Vdc, and the like) is measured (Step S3). Then, whether an abnormal state is generated in one or more of the measured data is determined (Step S4).

In the case where it is determined that an abnormal state is not generated, the various kinds of deposition conditions are not changed. In contrast, in the case where it is determined that an abnormal state is generated, inference is performed using a neural network to newly generate various kinds of deposition conditions (Step S5). The various kinds of deposition conditions generated are input to the control device, and the various kinds of deposition conditions are changed (Step S6). Subsequently, thin film formation continues on the basis of the various kinds of deposition conditions changed.

The process from Step S3 to Step S6 described above is performed at regular intervals of time during thin film formation. At the time when it is confirmed that the thin film has a desired film thickness, the thin film formation is terminated (Step S7). The deposition rate may be calculated in advance and the deposition time for obtaining the desired film thickness may be estimated from the deposition rate, in which case the timing of the termination of the thin film formation may be the timing when the deposition time passes.

The film quality and film thickness of thin films can be made uniform through the above steps. In addition, adjusting various kinds of deposition conditions during deposition makes it possible to form thin films without suspension of the thin film formation process. Since thin films can be formed without suspension of the thin film formation process, the productivity can be high.

### [Structure Example]

A structure example of the plasma CVD apparatus 600 of one embodiment of the present invention will be described below. FIG. 3 is a block diagram illustrating the structure of the plasma CND apparatus 600,

The plasma CVD apparatus 600 illustrated in FIG. 3 includes the control device 611, the treatment chamber 612, the arithmetic portion 613, the controller IC 614, a deposition condition input means 615, a gas supply means 616, an evacuation means 617, an electric power supply means 618, an electrode interval adjustment means 619, a temperature adjustment means 620, and a matching box 621. Note that the gas supply means 616, the evacuation means 617, the electrode interval adjustment means 619, and the temperature adjustment means 620 are each connected to the treatment chamber 612 or a component provided in the treatment chamber 612, such as an electrode. The electric power supply means 618 is connected to an electrode provided in the treatment chamber 612, through the matching box 621. In view of this, the gas supply means 616, the evacuation means 617, the electric power supply means 618, the electrode interval adjustment means 619, and the temperature adjustment means 620 are collectively referred to as several means in some cases.

The reaction chamber 612 is formed of a material having rigidity, such as aluminum or stainless steel, and is structured such that the inside can be vacuum evacuated. Although not shown, the treatment chamber 612 includes a first electrode and a second electrode. The first electrode and the second electrode are disposed to face each other. Note that the first electrode and the second electrode do not necessarily have a capacitively coupled type (parallel-plate type) structure. A different structure such as an inductively coupled type structure can also be employed as long as the structure can generate glow discharge plasma inside the treatment chamber by supply of two or more different high-frequency powers.

The deposition condition input means 615 is electrically connected to the control device 611 and the arithmetic portion 613. The deposition condition input means 615 is a device to which the various kinds of initial deposition conditions 601 can be input (see FIG. 1) and has a function of transmitting the various kinds of initial deposition conditions 601 that have been input, to the control device 611 and the arithmetic portion 613. Examples of the deposition condition input means 615 include a keyboard, a mouse, and an electronic device whose display portion has a touch panel function. The deposition condition input means 615 may be provided with an electronic device for displaying various kinds of deposition conditions.

The control device 611 is electrically connected to the controller IC 614, the deposition condition input means 615, and the several means (the gas supply means 616, the evacuation means 617, the electric power supply means 618, the electrode interval adjustment means 619, and the temperature adjustment means 620). The control device 611 has a function of receiving various kinds of deposition conditions that are transmitted from the controller IC 614 or the deposition condition input means 615 and controlling the several means connected to the treatment chamber 612.

The gas supply means 616 is connected to the first electrode in the treatment chamber 612. The gas supply means 616 is comprised of a cylinder filled with gas (a source gas, or a source gas and a carrier gas in the case of a plasma CVD apparatus), a pressure adjusting valve, a stop valve, a mass flow controller, and the like. In the treatment chamber 612, the first electrode has a surface which faces the substrate and which is processed into a shower-plate shape to have a plurality of holes. The gas supplied to the first electrode is supplied into the treatment chamber 612 through a hollow structure inside the first electrode such that the deposition condition (the gas 602A shown in FIG. 1) transmitted from the control device 611 is fulfilled.

The evacuation means 617 is connected to the treatment chamber 612 and has a function of adjusting, in the case of gas supply, the pressure in the treatment chamber 612 so that the pressure is kept at the pressure fulfilling the deposition condition (the pressure 602B in the treatment chamber shown in FIG. 1) transmitted from the control device 611. The evacuation means 617 includes a butterfly valve, a conductance valve, a dry pump, a mechanical booster pump, a turbo molecular pump, and the like. In the case where the butterfly valve and the conductance valve are disposed in parallel, the butterfly valve is closed and the conductance valve is operated, whereby the evacuation speed of gas is controlled, and thus, the pressure in the treatment chamber 612 can be kept in a predetermined range. Moreover, operation of the butterfly valve with higher conductance allows high-vacuum evacuation.

The electric power supply means 618 is connected to the first electrode in the treatment chamber 612 through the matching box 621. The second electrode is supplied with the ground potential and has such a shape that a substrate can be mounted. The AC power supplied between the electrodes in the treatment chamber 612 is supplied by the high-frequency power source of the electric power supply means 618 such that the deposition condition (the deposition power 602C shown in FIG. 1) transmitted from the control device 611 is fulfilled.

The electrode interval adjustment means 619 has a function of adjusting the interval between the first electrode and the second electrode in the treatment chamber 612. The interval between the _first electrode and the second electrode can be adjusted as appropriate. The interval is adjusted with a bellows so that the height of the second electrode can be changed in the treatment chamber 612. The interval is adjusted such that the deposition condition (the distance between the electrodes 602D shown in FIG. 1) transmitted from the control device 611 is fulfilled.

The temperature adjustment means 620 has a function of adjusting the substrate temperature. The temperature adjustment means 620 is connected to a substrate heater. The temperature of the substrate heater, which is provided on the second electrode, is controlled with a heater controller. In the case where the substrate heater is provided on the second electrode, a thermal conduction heating method is employed. For example, the substrate heater is composed of a sheath heater. The substrate temperature is adjusted with the substrate heater such that the deposition condition (the substrate temperature 602E shown in FIG. 1) transmitted from the control device 611 is fulfilled.

The matching box 621 is electrically connected to the electric power supply means 618 and the arithmetic portion 613. The matching box 621 has a function of effectively inducing the AC power supplied from the electric power supply means 618. In addition, the matching box 621 has a function of measuring data (Vpp, Vdc, and the like) during deposition and transmitting the measured data (the measurement value 603 shown in FIG. 1) to the arithmetic portion 613.

The arithmetic portion 613 is electrically connected to the controller IC 614, the deposition condition input means 615. and the matching box 621. The arithmetic portion 613 has a function of determining whether an abnormal state is generated and performing inference of various kinds of deposition conditions. As the arithmetic portion 613, a semiconductor device that can be used for a neural network can be used. The semiconductor device that can be used for a neural network will be described in detail in Embodiment 3 and the following embodiments.

The arithmetic portion 613 includes a memory. A memory including an OS transistor can be used as the memory. The memory including an OS transistor will be described in detail in Embodiment 4 and the following embodiments.

The controller IC 614 is electrically connected to the arithmetic portion 613 and the control device 611. The controller IC 614 has a function of controlling the timing of the inference performed by the arithmetic portion 613 and a function of controlling the control device 611.

### [Learning and Inference]

A neural network of one embodiment of the present invention preferably performs learning for determining whether an abnormal state is generated. Performing the learning makes it possible to determine whether an abnormal state is generated, Furthermore, the neural network preferably performs learning for performing inference of various kinds of deposition conditions, on the basis of the data measured during deposition. Performing the learning allows inference of various kinds of deposition conditions in the case where it is determined that an abnormal state is generated.

In one embodiment of the present invention, a parameter input to the neural network is, for example, measurement data accumulated in a certain period. For example, groups of data, where a group consists of the time when measurement is performed and various kinds of deposition conditions and measurement data at each time, are input to the neural network. For example, the various kinds of deposition conditions are the kind and flow rate or flow rate ratio of gas, the pressure in the treatment chamber, the deposition power, the distance between the electrodes, and the substrate temperature, and the measurement data is Vpp and Vdc. It is preferable that in the neural network of one embodiment of the present invention, changes in measurement data during a certain period over time be analyzed.

First, an example of learning for determining whether an abnormal state is generated is described. Whether an abnormal state is generated is determined by detecting the fact that the measurement data remains to be that which is different from the measurement data at the start of deposition. In the learning, input data is the time when measurement is performed and various kinds of deposition conditions at each time, and a teacher signal is the measurement data at each time. The output value is the measurement data calculated from various kinds of deposition conditions and a weight coefficient.

For example, the time when measurement is performed and various kinds of deposition conditions and measurement data at each time are input to the neural network. The neural network calculates an output value from the input data and the weight coefficient. In the case where the output value is different from the teacher signal, the weight coefficient is updated and an output value is recalculated from the updated weight coefficient. The neural network repetitively updates the weight coefficient until the output value and the teacher signal become equal to each other. The weight coefficient is determined in the above manner.

Furthermore, the threshold value of a change in the measurement data is supplied to the neural network in which the determined weight coefficient is stored. Thus, the learning for determining whether an abnormal state is generated ends.

Next, determination of whether an abnormal state is generated is described. First, a difference between the output value calculated from the input data during deposition and the determined weight coefficient and the data measured during the deposition is calculated. In the case where the period in which the difference is greater than or equal to the above threshold value becomes longer than a certain period, it is determined that an abnormal state is generated. In contrast, in the case where the difference is less than the above threshold value or in the case where the period in which the difference is greater than or equal to the above threshold value is not longer than a certain period, it is determined that an abnormal state is not generated.

In the above learning in this embodiment, the input data is the time when measurement is performed and various kinds of deposition conditions at each time, and the teacher signal is the measurement data at each time; however, the present invention is not limited thereto. The input data may be measurement data at each time and the teacher signal may be the time when measurement is performed and various kinds of deposition conditions at each time. In that case, whether an abnormal state is generated is determined on the basis of a difference between the output value calculated from the data measured during deposition and the determined weight coefficient and the input data during the deposition. In this manner, the weight coefficient used for the learning for determining whether an abnormal state is generated can be the same as the weight coefficient used for inference of various kinds of deposition conditions.

An example in which whether an abnormal state is generated is determined with the use of a neural network is described in this embodiment; however, the present invention is not limited thereto. This determination may be performed by a cumulative sum method, a neighbor method, a singular spectrum transformation method, or the like.

Next, an example of learning for performing inference of various kinds of deposition conditions will be described. In the learning, input data is the time when measurement is performed and the measurement data at each time, and a teacher signal is various kinds of deposition conditions at each time. For example, the measurement data is Vpp and Vdc, and the various kinds of deposition conditions are the kind and flow rate or flow rate ratio of gas, the pressure in the treatment chamber, the deposition power, the distance between the electrodes, and the substrate temperature. The output value is various kinds of deposition conditions calculated from the measurement data and a weight coefficient.

In the learning for performing inference of various kinds of deposition conditions, for example, the time when measurement is performed and various kinds of deposition conditions and measurement data at each time are input to the neural network. The neural network calculates an output value from the input data and the weight coefficient. In the case where the output value is different from the teacher signal, the weight coefficient is updated and an output value is recalculated from the updated weight coefficient. The neural network repetitively updates the weight coefficient until the output value and the teacher signal become equal to each other. Thus, the learning for performing inference of various kinds of deposition conditions ends.

In the case where it is determined that an abnormal state is generated, the weight coefficient is updated repetitively until the measurement data after the abnormal state is generated and the measurement data before the abnormal state is generated become equal to each other. The neural network performs inference of various kinds of deposition conditions with the use of the updated weight coefficient. The various kinds of deposition conditions calculated through the inference are input to the control device. In the above manner, the various kinds of deposition conditions can be changed.

[Correlation between Film Quality of Thin Film and Vpp and Vdc]

Correlation between the film quality of a thin film deposited using a plasma CVD apparatus and Vpp and Vdc measured during the deposition will be described below. Specifically, the thin film deposited using a plasma CVD apparatus is a silicon oxynitride film, and the film quality of the silicon oxynitride film was evaluated on the basis of the content of nitrogen oxide (NOₓ; x is greater than 0 and less than or equal to 2, preferably greater than or equal to 1 and less than or equal to 2) in the silicon oxynitride film. For the evaluation, Sample 1A to Sample 1F in each of which a silicon oxynitride film was deposited were prepared, and Sample 1A to Sample 1F were subjected to electron spin resonance (ESR) measurements. In addition, Vpp and Vdc during fabrication of Sample 1A to Sample 1F were measured.

Fabrication methods of Sample 1A to Sample 1F will be described. Sample 1A to Sample 1F are each a sample in which a silicon oxynitride film was deposited on glass to a thickness of 100 nm with a plasma CVD apparatus. The common conditions under which the silicon oxynitride films were deposited were a flow rate of a silane gas (SiH₄) of 1 sccm, a flow rate of a dinitrogen monoxide (N₂O) gas of 800 sccm, and a substrate temperature of 350° C.

The pressure in the treatment chamber at the time of the deposition of the silicon oxynitride films was 100 Pa for Sample A to Sample 1C and 200 Pa for Sample 1D to Sample 1F. The deposition power at the time of the deposition of the silicon oxynitride films was 50 W for Sample 1A and Sample 1D, 90 W for Sample 1B and Sample 1E, and 150 W for Sample 1C and Sample 1F.

Sample 1A to Sample 1F fabricated by the above-described methods were each subjected to an ESR measurement under the following conditions. The measurement temperature was 100 K; 1 mW of high-frequency power (microwave power) with 8.92 GHz was applied; and the direction of a magnetic field was parallel to the surface of the fabricated sample film. A lower spin density means a smaller number of defects in the film.

Note that in the ESR spectrum at 100 K or lower, the sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 corresponds to the sum of the spin densities of signals attributed to nitrogen oxide. Typical examples of nitrogen oxide include nitrogen monoxide and nitrogen dioxide. That is, the lower the sum of the spin densities of the first signal that appears at a g-factor of greater than or equal to 2.037 and less than or equal to 2.039, the second signal that appears at a g-factor of greater than or equal to 2.001 and less than or equal to 2.003, and the third signal that appears at a g-factor of greater than or equal to 1.964 and less than or equal to 1.966 is, the lower the content of nitrogen oxide in the silicon oxynitride film is.

FIG. 4 shows the spin densities of the signals attributed to nitrogen oxide in Sample 1A to Sample 1F. The spin densities here are each a value obtained by conversion of the measured spin number into the spin number per unit volume. A dashed-dotted line shown in FIG. 4 indicates the lower detection limit of the spin density. FIG. 4 reveals that a higher deposition power tends to lead to a higher spin density and a higher pressure in the treatment chamber tends to lead to a higher spin density.

Next, FIG. 5 shows the results of measuring Vpp and Vdc during the fabrication of Sample 1A to Sample 1F.

FIG. 5(A) shows Vpp measured during the fabrication of Sample 1A to Sample 1F. FIG. 5(A) reveals that a higher deposition power tends to lead to larger Vpp and a higher pressure in the treatment chamber tends to lead to larger Vpp.

FIG. 5(B) shows Vdc measured during the fabrication of Sample 1A to Sample 1F. FIG. 5(B) reveals that a higher deposition power tends to lead to smaller Vdc and a higher pressure in the treatment chamber tends to lead to larger Vdc. Accordingly, the various kinds of deposition conditions are found to correlate with Vpp and Vdc.

FIG. 6 shows the spin densities of the signals attributed to nitrogen oxide in Sample 1A to Sample 1F with respect to a function of Vpp and Vdc measured during the fabrication of Sample 1A to Sample 1F. In FIG. 6, the horizontal axis represents the value of the function f(Vpp, Vdc) of Vpp and Vdc and the vertical axis represents the logarithm of the spin density [spins/cm³]. FIG. 6 reveals that a larger value of the function f(Vpp, Vdc) tends to lead to a higher spin density of the signal attributed to nitrogen oxide. That is, the value of the function f(Vpp, Vdc) is found to correlate with the content of nitrogen oxide in the silicon oxynitride Accordingly, the film quality of the silicon oxynitride film is found to correlate with Vpp and Vdc.

This embodiment can be implemented in combination with any of the structures described in the other embodiments and the like, as appropriate.

### Embodiment 2

In this embodiment, an example of the thin film manufacturing apparatus described in the above embodiment will be described with reference to FIG. 7.

In manufacture of a semiconductor device described in an embodiment below as an example, it is preferable to use what is called a multi-chamber apparatus which includes a plurality of treatment chambers that allow successive deposition of different kinds of films. In the treatment chambers, a deposition treatment can be performed by a sputtering method, a CVD method, an MBE method, a PLD method, an ALD method, and the like. For example, in the case where one treatment chamber is used for performing a deposition treatment by a plasma CVD method, a gas supply means, an electric power supply means including a high-frequency power source, an evacuation means, and the like can be connected to the treatment chamber. When the apparatus including the treatment chamber has a structure similar to that of the apparatus described in the above embodiment, a plasma CVD apparatus using a neural network can be obtained.

In the case where a deposition treatment is performed in the treatment chamber by a sputtering method using the high-frequency power source, Vpp and Vdc can be acquired during the treatment. Thus, when the apparatus including the treatment chamber has a structure similar to that of the apparatus described in the above embodiment, a sputtering apparatus using a neural network can be obtained. The sputtering apparatus has a function of constantly measuring data (e.g., Vpp and Vdc) other than various kinds of deposition conditions during a deposition treatment by a sputtering method to monitor whether an abnormal state is generated in the data. In addition, the sputtering apparatus has a function of adjusting various kinds of deposition conditions by performing inference with the neural network when an abnormal state is detected. That is, the neural network enables control of a deposition treatment by a sputtering method.

In each treatment chamber, a substrate cleaning treatment, a plasma treatment, a reverse sputtering treatment, an etching treatment, an ashing treatment, a heat treatment, or the like may be performed. Performing different treatments as appropriate in the treatment chambers allows an insulator film, a conductor film, and a semiconductor film to be formed without exposure to the air.

In the case where a dry etching treatment is performed in the treatment chamber, Vpp and Vdc can be acquired during the treatment. Thus, when an apparatus including the treatment chamber has a structure similar to that of the apparatus described in the above embodiment, a dry etching apparatus using a neural network can be obtained. The thy etching apparatus has a function of constantly measuring data (e.g., Vpp and Vdc) other than etching conditions during dry etching to monitor whether an abnormal state is generated in the data. In addition, the dry etching apparatus has a function of adjusting etching conditions by performing inference with the neural network when an abnormal state is detected. That is, the neural network enables control of a dry etching treatment.

When there are data that can be constantly measured during a treatment besides various kinds of set conditions, the treatment, which is not limited to a deposition treatment by a plasma CVD method or a sputtering method and a dry etching treatment, may be controlled with the neural network on the basis of the various kinds of set conditions and the data.

Typical examples of a semiconductor functioning as a channel formation region of a semiconductor device that will be described in an embodiment below include an oxide semiconductor. Specifically, using an oxide semiconductor with a low impurity concentration and a low density of defect states (few oxygen vacancies) for the channel formation region of the semiconductor device makes it possible to fabricate a transistor with excellent electrical characteristics. Here, the state in which the impurity concentration is low and the density of defect states is low is referred to as highly purified intrinsic or substantially highly purified intrinsic.

Here, different kinds of thin films are formed successively without being exposed to the air for an oxide semiconductor, an insulator or a conductor positioned below the oxide semiconductor, and an insulator or a conductor positioned above the oxide semiconductor, whereby a substantially highly purified intrinsic oxide semiconductor whose impurity (in particular, water and hydrogen) concentration is reduced can be formed.

First, a structure example of the thin film manufacturing apparatus described in the above embodiment will be described with reference to FIG. 7. With the use of the apparatus illustrated in FIG. 7, a semiconductor, an insulator or a conductor positioned below the semiconductor, and an insulator or a conductor positioned above the semiconductor can be formed successively. Thus, entry of impurities (in particular, water and hydrogen) into the semiconductor can be inhibited.

FIG. 7 is a schematic top view of a single wafer multi-chamber apparatus 4000.

The apparatus 4000 includes an atmosphere-side substrate supply chamber 4010, an atmosphere-side substrate transfer chamber 4012 that transfers a substrate from the atmosphere-side substrate supply chamber 4010, a load lock chamber 4020a that loads a substrate and switches the pressure in the chamber from an atmospheric pressure to a reduced pressure or from a reduced pressure to an atmospheric pressure, an unload lock chamber 4020b that unloads a substrate and switches the pressure in the chamber from a reduced pressure to an atmospheric pressure or from an atmospheric pressure to a reduced pressure, a transfer chamber 4029 and a transfer chamber 4039 that transfer a substrate in a vacuum, a transport chamber 4030a and a transport chamber 4030b that connect the transfer chamber 4029 and the transfer chamber 4039, and a treatment chamber 4024a, a treatment chamber 4024h, a treatment chamber 4034a, a treatment chamber 4034b, a treatment chamber 4034c, a treatment chamber 4034d, and a treatment chamber 4034e that perform deposition or heating.

Note that different treatments can be performed in a plurality of treatment chambers in parallel. Thus, a stacked-layer structure of different kinds of films can be easily fabricated. Note that the number of parallel treatments performed can be the number of treatment chambers at a maximum. For example, the apparatus 4000 illustrated in FIG. 7 is an apparatus that includes seven treatment chambers. Therefore, seven deposition treatments can be performed at the same time using one apparatus (which is also referred to as “in-situ” in this specification).

On the other hand, the number of stacked layers that can be fabricated in a stacked-layer structure without exposure to the air is not necessarily the same as the number of treatment chambers. For example, in the case where a desired stacked-layer structure includes a plurality of layers of the same material, the layers can be provided in one treatment chamber; thus, it is possible to fabricate a stacked-layer structure whose number of the stacked layers is larger than the number of the treatment chambers installed.

The atmosphere-side substrate supply chamber 4010 includes a cassette port 4014 that holds a substrate and an alignment port 4016 that aligns a substrate. Note that a plurality of the cassette ports 4014 may be provided (for example, three cassette ports in FIG. 7).

The atmosphere-side substrate transfer chamber 4012 is connected to the load lock chamber 4020a and the unload lock chamber 4020b. The transfer chamber 4029 is connected to the load lock chamber 4020a, the unload lock chamber 4020b, the transport chamber 4030a, the transport chamber 4030b, the treatment chamber 4024a, and the treatment chamber 4024b. The transport chamber 4030a and the transport chamber 4030b are connected to the transfer chamber 4029 and the transfer chamber 4039. The transfer chamber 4039 is connected to the transport chamber 4030a, the transport chamber 4030b, the treatment chamber 4034a, the treatment chamber 4034b, the treatment chamber 4034c, the treatment chamber 4034d, and the treatment chamber 4034e.

Note that a gate valve 4028 or a gate valve 4038 is provided for a connecting portion of each chamber so that each chamber except the atmosphere-side substrate supply chamber 4010 and the atmosphere-side substrate transfer chamber 4012 can be independently kept under a vacuum. The atmosphere-side substrate transfer chamber 4012 includes a transfer robot 4018. The transfer chamber 4029 includes a transfer robot 4026 and the transfer chamber 4039 includes a transfer robot 4036. The transfer robot 4018, the transfer robot 4026, and the transfer robot 4036 each include a plurality of movable portions and an arm for holding a substrate and can transfer a substrate to each chamber.

Note that the numbers of transfer chambers, treatment chambers, load lock chambers, unload lock chambers, and transport chambers are not limited to the above and can be set as appropriate depending on the space for placement or the process conditions.

Particularly when a plurality of transfer chambers are provided, two or more transport chambers are preferably provided between one transfer chamber and another transfer chamber. For example, in the case where the transfer chamber 4029 and the transfer chamber 4039 are provided as illustrated in FIG. 7, the transport chamber 4030a and the transport chamber 4030b are preferably provided in parallel between the transfer chamber 4029 and the transfer chamber 4039.

When the transport chamber 4030a and the transport chamber 4030b are provided in parallel, for example, a step in which the transfer robot 4026 loads a substrate to the transport chamber 4030a and a step in which the transfer robot 4036 loads a substrate to the transport chamber 4030b can be performed at the same time. In addition, a step in which the transfer robot 4026 unloads a substrate from the transport chamber 4030b and a step in which the transfer robot 4036 unloads a substrate from the transport chamber 4030a can be performed at the same time. That is, production efficiency increases when a plurality of transfer robots are driven at the same time.

Although an example in which one transfer chamber includes one transfer robot and is connected to a plurality of treatment chambers is illustrated in FIG. 7, the present invention is not limited to this structure. One transfer chamber may include a plurality of transfer robots.

One or both of the transfer chamber 4029 and the transfer chamber 4039 are connected to a vacuum pump and a cryopump through valves. Accordingly, the transfer chamber 4029 and the transfer chamber 4039 can be evacuated with the use of the vacuum pump from an atmospheric pressure to a low vacuum or a medium vacuum (approximately several hundreds of pascals to 0.1 pascals) and then, with the valves switched, the transfer chamber 4029 and the transfer chamber 4039 can be evacuated with the use of the cryopump from a medium vacuum to a high vacuum or an ultra-high vacuum (approximately 0.1 Pa to 1×10⁻⁷ Pa).

Alternatively, two or more cryopumps may be connected in parallel to one transfer chamber, for example. With a plurality of cryopumps, even when one of the cryopumps is in regeneration, exhaust can be performed using another cryopump. Note that regeneration refers to a treatment for discharging molecules (or atoms) entrapped in a cryopump. When molecules (or atoms) are entrapped too much in a cryopump, the exhaust capability is lowered; therefore, it is preferable that regeneration be performed regularly.

Different treatments can be performed in the treatment chamber 4024a, the treatment chamber 4024b, the treatment chamber 4034a, the treatment chamber 4034b, the treatment chamber 4034c, the treatment chamber 4034d, and the treatment chamber 4034e in parallel. In other words, the substrate provided can be subjected to one or more treatments out of a deposition treatment by a sputtering method, a CVD method, an MBE method, a PLD method, an ALD method, or the like, a heat treatment, and a plasma treatment in the treatment chambers independently, in the treatment chamber, a deposition treatment may be performed after a heat treatment or a plasma treatment is performed.

Since a plurality of treatment chambers are provided in the apparatus 4000, it is possible to transfer a substrate without exposure to the air between treatments; thus, adsorption of impurities on the substrate can be inhibited. One or more treatments out of deposition treatments for various kinds of films, a heat treatment, and a plasma treatment can be performed in the treatment chambers independently, which makes it possible to freely determine the order of deposition, a heat treatment, and the like.

The load lock chamber 4020a may include a substrate delivery stage, a rear heater for heating a substrate from the rear surface, or the like. In the load lock chamber 4020a, when the pressure in the load lock chamber 4020a is increased from a reduced pressure state to an atmospheric pressure and becomes an atmospheric pressure, the substrate delivery stage receives a substrate from the transfer robot 4018 provided in the atmosphere-side substrate transfer chamber 4012. After that, the load lock chamber 4020a is evacuated into a vacuum to make a reduced pressure state, and then, the transfer robot 4026 provided in the transfer chamber 4029 receives the substrate from the substrate delivery stage.

Furthermore, the load lock chamber 4020a is connected to a vacuum pump and a cryopump through valves. Note that the unload lock chamber 4020b can have a structure similar to that of the load lock chamber 4020a.

Since the atmosphere-side substrate transfer chamber 4012 includes the transfer robot 4018, delivery and receipt of a substrate between the cassette port 4014 and the load lock chamber 4020a can be performed using the transfer robot 4018. Furthermore, a mechanism for inhibiting entry of dust or a particle, such as a high efficiency particulate air filter (HEPA filter), may be provided above the atmosphere-side substrate transfer chamber 4012 and the atmosphere-side substrate supply chamber 4010. The cassette port 4014 can store a plurality of substrates.

Entry of impurities into a semiconductor film can be favorably inhibited when an insulating film, a semiconductor film, and a conductive film are successively deposited with the use of the above apparatus 4000 without exposure to the air.

As described above, a stacked-layer structure including* a semiconductor film can be fabricated by successive deposition with the apparatus of one embodiment of the present invention. Therefore, entry of impurities such as hydrogen and water into a semiconductor film can be inhibited and a semiconductor film with a low density of defect states can be fabricated.

At least part of this embodiment can be implemented in combination with any of the other embodiments described in this specification as appropriate.

### Embodiment 3

In this embodiment, a structure example of a semiconductor device, which can be used in the neural network described in Embodiment 1, will be described.

As illustrated in FIG. 8(A), the neural network NN can be formed of the input layer IL, the output layer OL, and the middle layer (hidden layer) HL. The input layer IL, the output layer OL, and the middle layer HL each include one or more neurons (units). Note that the middle layer HL may be composed of one layer or two or more layers. A neural network including two or more middle layers HL can also be referred to as a deep neural network (DNN), and learning using a deep neural network can also be referred to as deep learning.

Input data is input to neurons of the input layer IL, output signals of neurons in the previous layer or the subsequent layer are input to neurons of the middle layer HL, and output signals of neurons in the previous layer are input to neurons of the output layer OL. Note that each neuron may be connected to all the neurons in the previous and subsequent layers (full connection), or may be connected to some of the neurons.

FIG. 8(B) illustrates an example of an operation with the neurons. Here, a neuron N and two neurons in the previous layer which output signals to the neuron N are illustrated. An output x₁ of a neuron in the previous layer and an output x₂ of a neuron in the previous layer are input to the neuron N. Then, in the neuron N, a total sum x₁w₁+x₂w₂ of a multiplication result (x₁w₁) of the output x₁ and a weight w₁ and a multiplication result (x₂w₂) of the output x₂ and a weight w₂ is calculated, and then a bias b is added as necessary, so that a value a=x₁w₁+x₂w₂+b is obtained. Then, the value a is converted with an activation function h, and an output signal y=h(a) is output from the neuron N.

As described above, the operation with the neurons includes the product-sum operation, that is, the operation that sums the products of the outputs and the weights of the neurons in the previous layer (x₁w₁+x₂w₂ described above). This product-sum operation may be performed using a program on software or using hardware. In the case where the product-sum operation is performed using hardware, a product-sum operation circuit can be used. Either a digital circuit or an analog circuit may be used as this product-sum operation circuit. In the case where an analog circuit is used as the product-sum operation circuit, the circuit scale of the product-sum operation circuit can be reduced, or higher processing speed and lower power consumption can be achieved by reduced frequency of access to a memory.

The product-sum operation circuit may be formed of a transistor including silicon (such as single crystal silicon) in a channel formation region (hereinafter also referred to as a Si transistor) or an OS transistor. An OS transistor is particularly suitable for a transistor included in an analog memory of the product-sum operation circuit because of its extremely low off-state current. Note that the product-sum operation circuit may be formed using both a Si transistor and an OS transistor. A configuration example of a semiconductor device having a function of the product-sum operation circuit will be described below.

### <Configuration Example of Semiconductor Device>

FIG. 9 illustrates a configuration example of a semiconductor device MAC having a function of performing an operation of a neural network. The semiconductor device MAC has a function of performing a product-sum operation of first data corresponding to the connection strength between neurons (weight) and second data corresponding to input data. Note that the first data and the second data can each be analog data or multilevel data (discrete data). The semiconductor device MAC also has a function of converting data obtained by the product-sum operation with an activation function.

The semiconductor device MAC includes a cell array CA, a current source circuit CS, a current mirror circuit CM, a circuit WDD, a circuit WLD, a circuit CLD, an offset circuit OFST, and an activation function circuit ACTV.

The cell array CA includes a plurality of memory cells MC and a plurality of memory cells MCref. FIG. 9 illustrates a configuration example in which the cell array CA includes the memory cells MC in m rows and n columns (MC[1, 1] to MC[m, n]) and the m memory cells MCref (MCref[1] to MCref[m]) (m and n are integers greater than or equal to 1). The memory cells MC each have a function of storing the first data. In addition, the memory cells MCref each have a function of storing reference data used for the product-sum operation. Note that the reference data can be analog data or multilevel data.

The memory cell MC[i, j] (i is an integer greater than or equal to 1 and less than or equal to m, and j is an integer greater than or equal to 1 and less than or equal to n) is connected to a wiring WL[i], a wiring RW[i], a wiring WD[j], and a wiring BL[j]. In addition, the memory cell MCref[i] is connected to the wiring WI,[i], the wiring RW[i], a wiring WDref, and a wiring BLref. Here, a current flowing between the memory cell MC[i, j] and the wiring BL[j] is denoted by I_{MC[i, j]}, and a current flowing between the memory cell MCref[i] and the wiring BLref is denoted by I_{MCref[i]}.

FIG. 10 illustrates a specific configuration example of the memory cells MC and the memory cells MCref. Although the memory cells MC[1, 1] and MC[2, 1] and the memory cells MCref[1 ] and MCref[2] are illustrated in FIG. 10 as typical examples, similar configurations can be used for other memory cells MC and memory cells MCref The memory cells MC and the memory cells MCref each include transistors Tr11 and Tr12 and a capacitor C11. Here, the case where the transistor Tr11 and the transistor Tr12 are n-channel transistors will be described.

In the memory cell MC, a gate of the transistor Tr11 is connected to the wiring WL, one of a source and a drain of the transistor Tr11 is connected to a gate of the transistor Tr12 and a first electrode of the capacitor C11, and the other of the source and the drain of the transistor Tr11 is connected to the wiring WD. One of a source and a drain of the transistor Tr12 is connected to the wiring BL, and the other of the source and the drain of the transistor Tr12 is connected to a wiring VR. A second electrode of the capacitor C11 is connected to the wiring RW. The wiring VR is a wiring having a function of supplying a predetermined potential. Here, the case where a low power supply potential (e.g., a ground potential) is supplied from the wiring VR is described as an example.

A node connected to the one of the source and the drain of the transistor Tr11, the gate of the transistor Tr12, and the first electrode of the capacitor C11 is referred to as a node NM. The nodes NM in the memory cells MC[1, 1] and MC[2, 1] are referred to as nodes NM[1, 1] and NM[2, 1], respectively.

The memory cells MCref have a configuration similar to that of the memory cell MC. However, the memory cells MCref are connected to the wiring WDref instead of the wiring WD and connected to the wiring BLref instead of the wiring BL. Nodes in the memory cells MCref[1] and MCref[2] each of which is connected to the one of the source and the drain of the transistor Tr11, the gate of the transistor Tr12, and the first electrode of the capacitor C11 are referred to as nodes NMref[1] and NMref[2], respectively.

The node NM and the node NMref function as retention nodes of the memory cell MC and the memory cell MCref, respectively. The first data is retained in the node NM and the reference data is retained in the node NMref. Currents I_{MC[1, 1]} and I_{MC[2, 1]} from the wiring BL[1] flow to the transistors Tr12 of the memory cells MC[1, 1] and MC[2, 1], respectively. Currents I_{MCref[1]} and I_{MCref[1, 2]} from the wiring BLref flow to the transistors Tr12 of the memory cells MCref[1] and MCref[2], respectively.

Since the transistor Tr11 has a function of retaining the potential of the node NM or the node NMref, the off-state current of the transistor Tr11 is preferably low. Thus, it is preferable to use an OS transistor, which has an extremely low off-state current, as the transistor Tr11. This inhibits a change in the potential of the node NM or the node NMref, so that the operation accuracy can be improved. Furthermore, operations of refreshing the potential of the node NM or the node NMref can be performed less frequently, which leads to a reduction in power consumption

There is no particular limitation on the transistor Tr12, and for example, a Si transistor, an OS transistor, or the like can be used. In the case where an OS transistor is used as the transistor Tr12, the transistor Tr12 can be manufactured with the same manufacturing apparatus as the transistor Tr11, and accordingly manufacturing cost can be reduced. Note that the transistor Tr12 may be an n-channel transistor or a p-channel transistor.

The current source circuit CS is connected to the wirings BL[1] to BL[n] and the wiring BLref. The current source circuit CS has a function of supplying currents to the wirings BL[1] to BL[n] and the wiring BLref. Note that the value of the current supplied to the wirings BL[1] to BL[n] may be different from the value of the current supplied to the wiring BLref. Here, the current supplied from the current source circuit CS to the wirings BL[1] to BL[n] is denoted by I_{C}, and the current supplied from the current source circuit CS to the wiring BLref is denoted by I_{Cref}.

The current mirror circuit CM includes wirings IL[1] to IL[n] and a wiring ILref. The wirings IL[1] to IL[n] are connected to the wirings BL[1] to BL[n], respectively, and the wiring ILref is connected to the wiring BLref. Here, portions where the wirings IL[1] to IL[n] are connected to the respective wirings BL[1] to BL[n] are referred to as nodes NP[1] to NP[n]. Furthermore, a portion where the wiring ILref is connected to the wiring BLref is referred to as a node NPref.

The current mirror circuit CM has a function of making a current I_{CM} corresponding to the potential of the node NPref flow to the wiring ILref and a function of making this current I_{CM} flow also to the wirings IL[1] to IL[n]. In the example illustrated in FIG. 9, the current I_{CM} is discharged from the wiring BLref to the wiring ILref, and the current I_{CM} is discharged from the wirings BL[1] to BL[n] to the wirings IL[1] to IL[n]. Furthermore, currents flowing from the current mirror circuit CM to the cell array CA through the wirings BL[1] to BL[n] are denoted by I_{B}[1] to I_{B}[n]. Furthermore, a current flowing from the current mirror circuit CM to the cell array CA through the wiring BLref is denoted by I_{Bref}.

The circuit WDD is connected to the wirings WD[1] to WD[n] and the wiring WDref The circuit WDD has a function of supplying a potential corresponding to the first data to be stored in the memory cells MC to the wirings WD[1] to WD[n]. The circuit WDD also has a function of supplying a potential corresponding to the reference data to be stored in the memory cell MCref to the wiring WDref. The circuit WLD is connected to wirings WL[1] to WL[m]. The circuit WLD has a function of supplying a signal for selecting the memory cell MC or the memory cell MCref to which data is to be written, to any of the wirings WL[1] to WL[m]. The circuit CLD is connected to the wirings RW[1] to RW[m]. The circuit CLD has a function of supplying a potential corresponding to the second data to the wirings RW[1] to RW[m].

The offset circuit OFST is connected to the wirings BL[1] to BL[ n] and wirings OL[1] to OL[n]. The offset circuit OFST has a function of detecting the amount of currents flowing from the wirings BL[1] to BL[n] to the offset circuit OFST and/or the amount of change in the currents flowing from the wirings BL[1] to BL[n] to the offset circuit OFST. The offset circuit OFST also has a function of outputting detection results to the wirings OL[1] to OL[n]. Note that the offset circuit OFST may output currents corresponding to the detection results to the wirings OL, or may convert the currents corresponding to the detection results into voltages to output the voltages to the wirings OL. The currents flowing between the cell array CA and the offset circuit OFST are denoted by I_{α}[1] to I_{α}[n].

FIG. 11 illustrates a configuration example of the offset circuit OFST. The offset circuit OFST illustrated in FIG. 11 includes circuits OC[1] to OC[n]. The circuits OC[1] to OC[n] each include a transistor Tr21, a transistor Tr22, a transistor Tr23, a capacitor C21, and a resistor R1. Connection relations of the elements are illustrated in FIG. 11. Note that a node connected to a first electrode of the capacitor C21 and a first terminal of the resistor RI is referred to as a node Na. In addition, a node connected to a second electrode of the capacitor C21, one of a source and a drain of the transistor Tr21, and a gate of the transistor Tr22 is referred to as a node Nb.

A wiring VrefL has a function of supplying a potential Vref, a wiring VaL has a function of supplying a potential Va, and a wiring VbL has a function of supplying a potential Vb. Furthermore, a wiring VDDL has a function of supplying a potential VDD, and a wiring VSSL has a function of supplying a potential VSS. Here, the case where the potential VDD is a high power supply potential and the potential VSS is a low power supply potential is described. A wiring RST has a function of supplying a potential for controlling the conduction state of the transistor Tr21. The transistor Tr22, the transistor Tr23, the wiring VDDL, the wiring VSSL, and the wiring VbL form a source follower circuit.

Next, an operation example of the circuits OC[1] to OC[n] will be described. Note that although an operation example of the circuit OC[1] is described here as a typical example, the circuits OC[2] to OC[n] can operate in a similar manner. First, when a first current flows to the wiring BL[1], the potential of the node Na becomes a potential corresponding to the first current and the resistance value of the resistor R1. At this time, the transistor Tr21 is in an on state, and thus the potential Va is supplied to the node Nb. Then, the transistor Tr21 is brought into an off state.

Next, when a second current flows to the wiring BL[1], the potential of the node Na changes to a potential corresponding to the second current and the resistance value of the resistor R1. At this time, since the transistor Tr21 is in an off state and the node Nb is in a floating state, the potential of the node Nb changes because of capacitive coupling, following the change in the potential of the node Na. Here, when the amount of change in the potential of the node Na is ΔV_{Na} and the capacitive coupling coefficient is 1, the potential of the node Nb is Va+ΔV_{Na}. When the threshold voltage of the transistor Tr22 is Vat, a potential Va+ΔV_{Na}−Vₜₕ is output from the wiring OL[1]. Here, when Va=Vₜₕ, the potential ΔV_{Na} can be output from the wiring OL[1].

The potential ΔV_{Na} is determined by the amount of change from the first current to the second current, the resistance of the resistor R1, and the potential Vref. Here, since the resistance of the resistor R1 and the potential Vref are known, the amount of change in the current flowing to the wiring BL can be found from the potential ΔV_{Na}.

A signal corresponding to the amount of current and/or the amount of change in the current that are/is detected by the offset circuit OFST as described above is input to the activation function circuit ACTV through the wirings OL[1] to OL[n].

The activation function circuit ACTV is connected to the wirings OL[1] to OL[n] and wirings NIL[ 1] to NIL[n]. The activation function circuit ACTV has a function of performing an operation for converting the signal input from the offset circuit OFST in accordance with the predefined activation function. As the activation function, for example, a sigmoid function, a tank function, a softmax function, a ReLU function, a threshold function, or the like can be used. The signal converted by the activation function circuit ACTV is output as output data to the wirings NIL[1] to NIL[n].

### <Operation Example of Semiconductor Device>

The product-sum operation of the first data and the second data can be performed using the above semiconductor device MAC. An operation example of the semiconductor device MAC at the time of performing the product-sum operation is described below.

FIG. 12 shows a timing chart of the operation example of the semiconductor device MAC. FIG. 12 shows changes in the potentials of the wiring WL[1], the wiring WL[2], the wiring WD[1], the wiring WDref, the node NM[1, 1], the node NM[2, 1], the node NMref[1], the node NMref[2], the wiring RW[1], and the wiring RW[2] in FIG. 10 and changes in the values of a current I_{B}[1]−I_{α}[1] and the current I_{Bref}. The current I_{B}[1]−I_{α}[1] corresponds to the sum total of the currents flowing from the wiring BL[ I] to the memory cells MC[1, 1] and MC[2, 1].

Although an operation is described with a focus on the memory cells MC[1, 1] and MC[2, 1] and the memory cells MCref[1] and MCref[2] illustrated in FIG. 10 as a typical example, the other memory cells MC and the other memory cells MCref can be operated in a similar manner.

### [Storage of First Data]

First, in a period from Time T01 to Time T02, the potential of the wiring WL[1] becomes a high level (High), the potential of the wiring WD[1] becomes a potential greater than a ground potential (GND) by V_{PR}−V_{W[1, 1]}, and the potential of the wiring WDref becomes a potential greater than the ground potential by V_{PR}. The potentials of the wiring RW[1] and the wiring RW[2] become reference potentials (REFP). Note that the potential is a potential corresponding to the first data stored in the memory cell MC[1, 1]. The potential V_{PR} is a potential corresponding to the reference data. Thus, the transistors Tr11 included in the memory cell MC[1, 1] and the memory cell MCref[1] are brought into on states, and the potential of the node NM[1, 1] becomes V_{PR}−V_{W[1, 1]} and the potential of the node NMref[1] becomes V_{PR}.

In this case, a current I_{MC[1, 1], 0} flowing from the wiring BL[1] to the transistor Tr12 in the memory cell MC[1, 1] can be expressed by the following formula. Here, k is a constant determined by the channel length, the channel width, the mobility, the capacitance of a gate insulator, and the like of the transistor Tr12. Furthermore, Vth is the threshold voltage of the transistor Tr12.

I_{MC[1, 1], 0}=k(V_{PR}−V_{W[1, 1]}−Vₜₕ)² (E1)

Furthermore, a current I_{MCref[1], 0} flowing from the wiring BLref to the transistor Tr12 in the memory cell MCref[1] can be expressed by the following formula.

I_{MCref[1], 0}=k(V_{PR}−Vₜₕ)² (E2)

Next, in a period from Time T02 to Time T03, the potential of the wiring WL[1] becomes a low level (Low). Consequently, the transistors Tr11 included in the memory cell MC[1, 1] and the memory cell MCref[1] are brought into off states, and the potentials of the node NM[1, 1] and the node NMref[1] are retained.

As described above, an OS transistor is preferably used as the transistor Tr11. This can suppress the leakage current of the transistor Tr11, so that the potentials of the node NM[1, 1] and the node NMref[1] can be retained accurately.

Next, in a period from Time T03 to Time T04, the potential of the wiring WL[2] becomes the high level, the potential of the wiring WD[1] becomes a potential greater than the ground potential by V_{PR}−V_{W[2, 1]}, and the potential of the wiring WDref becomes a potential greater than the ground potential by V_{PR}. Note that the potential V_{W[2, 1]} is a potential corresponding to the first data stored in the memory cell MC[2, 1]. Thus, the transistors Tr11 included in the memory cell MC[2, 1] and the memory cell MCref[2] are brought into on states, and the potential of the node NM[2, 1] becomes V_{PR}−V_{W[2, 1]} and the potential of the node NMref[2] becomes V_{PR}.

In this case, a current I_{MC[2, 1], 0} flowing from the wiring BL[1] to the transistor Tr12 in the memory cell MC[2, 1] can be expressed by the following formula.

I_{MC[2, 1], 0}=k(V_{PR}−V_{W[2, 1]}−Vₜₕ)² (E3)

Furthermore, a current I_{MCref[2], 0} flowing from the wiring BLref to the transistor Tr12 in the memory cell MCref[2] can be expressed by the following formula.

I_{MCref[2], 0}=k(V_{PR}−Vₜₕ)² (E4)

Next, in a period from Time T04 to Time T05, the potential of the wiring WL[2] becomes the low level. Consequently, the transistors Tr11 included in the memory cell MC[2, 1] and the memory cell MCref[2] are brought into off states, and the potentials of the node NM[2, 1] and the node NMref[2] are retained.

Through the above operation, the first data is stored in the memory cells MC[1, 1] and MC[2, 1], and the reference data is stored in the memory cells MCref[1] and MCref[2].

Here, currents flowing through the wiring BL[1] and the wiring BLref in the period from Time T04 to Time T05 are considered. A current is supplied from the current source circuit CS to the wiring BLref. The current flowing through the wiring BLref is discharged to the current mirror circuit CM and the memory cells MCref[1] and MCref[2]. The following formula holds where I_{Cref} is the current supplied from the current source circuit CS to the wiring BLref and I_{CM, 0} is the current discharged from the wiring BLref to the wiring ILref by the current mirror circuit CM.

I_{Cref}−I_{CM, 0}=I_{MCref[1], 0}+I_{MCref[2], 0} (E5)

A current from the current source circuit CS is supplied to the wiring BL[1]. The current flowing through the wiring BL[1] is discharged to the current minor circuit CM and the memory cells MC[1, 1] and MC[2, 1]. Furthermore, the current flows from the wiring BL[] to the offset circuit OFST. The following formula holds where In is the current supplied from the current source circuit CS to the wiring BL[1] and I_{60 , 0} is the current flowing from the wiring BL[1] to the offset circuit OFST.

I_{C}−I_{CM, 0}=I_{MC[1, 1], 0}+I_{MC[2, 1], 0}+I_{α, 0} (E6)

[Product-sum operation of first data and second data]

Next, in a period from Time T05 to Time T06, the potential of the wiring RW[1] becomes a potential greater than the reference potential by V_{X[1]}. At this time, the potential V_{X[1]} is supplied to the capacitor C11 in each of the memory cell MC[1, 1] and the memory cell MCref[1], so that the potential of the gate of the transistor Tr12 is increased because of capacitive coupling. Note that the potential V_{X[}1_{]} is a potential corresponding to the second data supplied to the memory cell MC[1, 1] and the memory cell MCref[1].

The amount of change in the potential of the gate of the transistor Tr12 corresponds to the value obtained by multiplying the amount of change in the potential of the wiring RW by a capacitive coupling coefficient determined by the memory cell configuration. The capacitive coupling coefficient is calculated using the capacitance of the capacitor C11, the gate capacitance of the transistor Tr12, the parasitic capacitance, and the like. In the following description, for convenience, the amount of change in the potential of the wiring RW is equal to the amount of change in the potential of the gate of the transistor Tr12, that is, the capacitive coupling coefficient is 1. In practice, the potential V_{X} can be determined in consideration of the capacitive coupling coefficient.

When the potential is supplied to the capacitors C11 in the memory cell MC[1, 1] and the memory cell MCref[1], the potentials of the node NM[1, 1] and the node NMref[1] each increase by V_{X[1]}.

Here, a current I_{MC[1, 1], 1} flowing from the wiring BL[1] to the transistor Tr12 in the memory cell MC[1, 1] in the period from Time T05 to Time T06 can be expressed by the following formula.

I_{MC[1, 1], 1}=k(V_{PR}−V_{W[1, 1]}+V_{X[1]}−Vₜₕ)² (E7)

That is, when the potential is supplied to the wiring RW[1], the current flowing from the wiring BL[1] to the transistor Tr12 in the memory cell MC[1, 1] increases by ΔI_{MC[1, 1]}=I_{MC[1, 1], 1}−I_{MC[1, 1], 0}.

A current I_{MCref[1], 1} flowing from the wiring BLref to the transistor Tr12 in the memory cell MCref[1] in the period from Time T05 to Time T06 can be expressed by the following formula.

I_{MCref[1], 1}=k(V_{PR}+V_{X[1]}−Vₜₕ)² (E8)

That is, when the potential is supplied to the wiring RW[1], the current flowing from the wiring BLref to the transistor Tr12 in the memory cell MCref[1] increases by ΔI_{MCref}[1]=I_{MCref[1], 1}−I_{MCref[1], 0}.

Furthermore, currents flowing through the wiring BL[1] and the wiring BLref are considered. The current I_{Cref} is supplied from the current source circuit CS to the wiring BLref. The current flowing through the wiring BLref is discharged to the current mirror circuit CM and the memory cells MCref[1] and MCref[2]. The following formula holds where I_{CM, 1} is the current discharged from the wiring BLref to the current mirror circuit CM.

I_{Cref}−I_{CM, 1}=I_{MCref[1], 1}+I_{MCref[2], 0} (E9)

The current I_{C} from the current source circuit CS is supplied to the wiring BL[1]. The current flowing through the wiring BL[1] is discharged to the current mirror circuit CM and the memory cells MC[1, 1] and MC[2, 1]. Furthermore, the current flows from the wiring BL[1] to the offset circuit OFST. The following formula holds where I_{α, 1} is the current flowing from the wiring BL[1] to the offset circuit OFST.

I_{C}−I_{CM,1}=I_{MC[1, 1]1}+I_{MC[2, 1], 0}+I_{α, 1} (E10)

In addition, from the formula (E1) to the formula (E10), a difference between the current I_{α, 0} and the current I_{α, 1} (differential current ΔI_{α}) can be expressed by the following formula.

ΔI_{α}=I_{60 , 1}−I_{60 , 0}=2kV_{W[1, 1]}V_{X[1]} (E11)

Thus, the differential current ΔI₆₀ is a value corresponding to the product of the potential V_{W[1]} and the potential V_{X[1]}.

After that, in a period from Time T06 to Time T07, the potential of the wiring RW[1] becomes the reference potential, and the potentials of the node NM[1, 1] and the node NMref[1] become similar to the potentials in the period from Time T04 to Time T05.

Next, in a period from Time T07 to Time T08, the potential of the wiring RW[1] becomes a potential greater than the reference potential by V_{X[1]}, and the potential of the wiring RW[2] becomes a potential greater than the reference potential by V_{X[2]}. Accordingly, the potential V_{X[1]} is supplied to the capacitor C11 in each of the memory cell MC[1, 1] and the memory cell MCref[1], and the potentials of the node NM[1, 1] and the node NMref[1] each increase by V_{X[1]} because of capacitive coupling. Furthermore, the potential V_{X[2]} is supplied to the capacitor C11 in each of the memory cell MC[2, 1] and the memory cell MCref[2], and the potentials of the node NM[2, 1] and the node NMref[2] each increase by V_{X[2]} because of capacitive coupling.

Here, a current I_{MC[2, 1], 1} flowing from the wiring BL[1] to the transistor Tr12 in the memory cell MC[2, 1] in the period from Time T07 to Time T08 can be expressed by the following formula.

I_{MC[2, 1], 1}=k(V_{PR}−V_{W[2, 1]}+V_{X[2]}−Vₜₕ)² (E12)

That is, when the potential V_{X[2]} is supplied to the wiring RW[2], the current flowing from the wiring BL[] to the transistor Tr12 in the memory cell MC[2, 1] increases by ΔI_{MC[2, 1]}=I_{MC[2, 1], 1}−I_{MC[2, 1], 0}.

A current I_{MCref[2], 1} flowing from the wiring BLref to the transistor Tr12 in the memory cell MCref[2] in the period from Time T07 to Time T08 can be expressed by the following formula.

I_{MCref[2], 1}=k(V_{PR}+V_{X[2]}−Vₜₕ)² (E13)

That is, when the potential V_{X[2]} is supplied to the wiring RW[2], the current flowing from the wiring BLref to the transistor Tr12 in the memory cell MCref[2] increases by ΔI_{MCref[2]}=I_{MCref,[2],1}−I_{MCref[2], 0}.

Furthermore, currents flowing through the wiring BL[1] and the wiring BLref are considered. The current I_{Cref} is supplied from the current source circuit CS to the wiring BLref. The current flowing through the wiring BLref is discharged to the current mirror circuit CM and the memory cells MCref[1] and MCref[2]. The following formula holds where I_{CM, 2} is the current discharged from the wiring BLref to the current mirror circuit CM.

I_{Cref}−I_{CM, 2}=I_{MCref[1], 1}+I_{MCref[2], 1} (E14)

The current 1c from the current source circuit CS is supplied to the wiring BL[1]. The current flowing through the wiring BL[1] is discharged to the current mirror circuit CM and the memory cells MC[1, 1] and MC[2, 1], Furthermore, the current flows from the wiring BL[1] to the offset circuit OFST. The following formula holds where I_{α, 2} is the current flowing from the wiring BL[1] to the offset circuit OFST.

I_{C}−I_{CM, 2}=I_{MC[1, 1], 1}+I_{MC[2, 1], 1}+I_{α, 2} (E15)

In addition, from the formula (E1) to the formula (E8) and the formula (E12) to the formula (E15), a difference between the current ΔI_{α, 0} and the current ΔI_{α, 2} (differential current ΔI_{α}) can be expressed by the following formula.

ΔI_{α}=I_{α, 2}−I_{α, 0}=2k(V_{W[1, 1]}V_{X[1]}+V_{W[2, 1]}V_{X[2]}) (E16)

Thus, the differential current ΔI_{α} is a value corresponding to the sum of the product of the potential V_{W[1, 1]} and the potential V_{X[1]} and the product of the potential V_{W[2, 1]} and the potential V_{X[2]}.

After that, in a period from Time T08 to Time T09, the potentials of the wirings RW[1] and RW[2] become the reference potential, and the potentials of the nodes NM[1, 1 ] and NM[2, 1] and the nodes NMref[1] and NMref[2] become similar to the potentials in the period from Time T04 to Time T05.

As represented by the formula (E11) and the formula (E16), the differential current ΔI_{α} input to the offset circuit OFST can be calculated from the formula including a product term of the potentials V_{W} corresponding to the first data (weight) and the potential V_{X} corresponding to the second data (input data). In other words, measurement of the differential current ΔI_{α} with the offset circuit OFST gives the result of the product-sum operation of the first data and the second data.

Note that although the memory cells MC[1, 1] and MC[2, 1] and the memory cells MCref[1] and MCref[2] are particularly focused on in the above description, the number of the memory cells MC and the memory cells MCref can be freely set. In the case where the number m of rows of the memory cells MC and the memory cells MCref is an arbitrary number i, the differential current ΔI_{α} can be expressed by the following formula.

ΔI_{α}=2kΣᵢV_{W[1, 1]}V_{X[i]} (E17)

When the number n of columns of the memory cells MC and the memory cells MCref is increased, the number of product-sum operations executed in parallel can be increased.

The product-sum operation of the first data and the second data can be performed using the semiconductor device MAC as described above. Note that the use of the configuration of the memory cells MC and the memory cells MCref in FIG. 10 allows the product-sum operation circuit to be formed of fewer transistors. Accordingly, the circuit scale of the semiconductor device MAC can be reduced.

In the case where the semiconductor device MAC is used for the operation in the neural network, the number m of rows of the memory cells MC can correspond to the number of pieces of input data supplied to one neuron and the number n of columns of the memory cells MC can correspond to the number of neurons. For example, the case where a product-sum operation using the semiconductor device MAC is performed in the middle layer HL in FIG. 8(A) is considered. In this case, the number m of rows of the memory cells MC can be set to the number of pieces of input data supplied from the input layer IL (the number of neurons in the input layer IL), and the number n of columns of the memory cells MC can be set to the number of neurons in the middle layer HL.

Note that there is no particular limitation on the configuration of the neural network for which the semiconductor device MAC is used. For example, the semiconductor device MAC can also be used for a convolutional neural network (CNN), a recurrent neural network (RNN), an autoencoder, a Boltzmann machine (including a restricted Boltzmann machine), or the like.

The product-sum operation in the neural network can be performed using the semiconductor device MAC as described above. Furthermore, the memory cells MC and the memory cells MCref illustrated in FIG. 10 are used for the cell array CA, whereby an integrated circuit with improved operation accuracy, lower power consumption, or a reduced circuit scale can be provided.

This embodiment can be combined with the description of the other embodiments as appropriate.

### Embodiment 4

In this embodiment, a NOSRAM will be described as an example of the memory device of one embodiment of the present invention that uses an OS transistor and a capacitor, with reference to FIG. 13 and FIG. 14. A NOSRAM (registered trademark) is an abbreviation of “Nonvolatile Oxide Semiconductor Random Access Memory”, which indicates a RAM including a gain cell (2T or 3T) memory cell. Note that hereinafter, a memory device using an OS transistor, such as the NOSRAM, is referred to as an OS memory in some cases.

A memory device in which OS transistors are used in memory cells (hereinafter referred to as an OS memory) is used in a NOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

### <NOSRAM 1600>

FIG. 13 illustrates a configuration example of a NOSRAM. A NOSRAM 1600 illustrated in FIG. 13 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL, a plurality of word lines RWL, a plurality of bit lines BL, and a plurality of source lines SL. The word lines WWL are write word lines and the word lines RWL are read word lines. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals from the outside (e.g., a chip enable signal and a write enable signal) to generate control signals for the row driver 1650, the column driver 1660, and the output driver 1670.

The row driver 1650 has a function of selecting a row to be accessed. The row driver 1650 includes a row decoder 1651 and a word line driver 1652.

The column driver 1660 drives a source line S1_, and a bit line BL. The column driver 1660 includes a column decoder 1661, a write driver 1662, and a digital-analog converter circuit (DAC) 1663.

The DAC 1663 converts 3-bit digital data into an analog voltage. The DAC 1663 converts 32-bit data WDA[31:0] into an analog voltage per 3 bits.

The write driver 1662 has a function of precharging the source line SL, a function of bringing the source line SL into an electrically floating state, a function of selecting the source line SL, a function of inputting a writing voltage generated by the DAC 1663 to the selected source line SL, a function of precharging the bit line BL, a function of bringing the bit line BL into an electrically floating state, and the like.

The output driver 1670 includes a selector 1671, an analog-digital converter circuit (ADC) 1672, and an output buffer 1673. The selector 1671 selects a source line SL to be accessed and transmits the potential of the selected source line SL to the ADC 1672. The ADC 1672 has a function of converting an analog voltage into 3-bit digital data. The potential of the source line SL is converted into 3-bit data in the ADC 1672, and the output buffer 1673 retains the data output from the ADC 1672.

### [Memory Cell]

FIG. 14(A) is a circuit diagram illustrating a configuration example of the memory cell 1611. The memory cell 1611 is a 2T gain cell and is electrically connected to the word line WWL, the word line RWL, the bit line BL, the source line SL, and the wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the potential of the node SN. The node SN is a data retaining node and corresponds to a gate of the transistor MP61 here.

The write transistor of the memory cell 1611 is formed using the OS transistor MO61; thus, the NOSRAM 1600 can retain data for a long time.

In the example of FIG. 14(A), a common bit line is used for writing and reading; alternatively, as illustrated in FIG. 14(B), a bit line WBL functioning as a write bit line and a bit line RBL functioning as a read bit line may be provided.

FIG. 14(C) to FIG. 14(E) illustrate other configuration examples of the memory cell. FIG. 14(C) to FIG. 14(E) illustrate examples where the write bit line and the read bit line are provided; however, as illustrated in FIG. 14(A), a bit line used both in writing and reading may be provided.

A memory cell 1612 illustrated in FIG. 14(C) is a modification example of the memory cell 1611 where the read transistor is changed into an n-channel transistor (MN61). The transistor MN61 may be an OS transistor or a Si transistor.

The OS transistors MO61 in the memory cell 1611 and the memory cell 1612 may each be an OS transistor with no second gate.

A memory cell 1613 illustrated in FIG. 14(D) is a 3T gain cell and is electrically connected to the word line WWL, the word line RWL, the bit line WBL, the bit line RBL, the source line SL, the wiring BGL, and a wiring PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

A memory cell 1614 illustrated in FIG. 14(E) is a modification example of the memory cell 1613 where the read transistor and the selection transistor are changed into n-channel transistors (a transistor MN62 and a transistor MN63). The transistor MN62 and the transistor MN63 may each be an OS transistor or a Si transistor.

The OS transistors provided in the memory cell 1611 to the memory cell 1614 may each be a transistor with no second gate or a transistor with a second gate.

There is theoretically no limitation on the number of rewriting operations of the NOSRAM 1600 because data is rewritten by charging and discharging of the capacitor C61 or the capacitor C62; and data can be written and read with low energy. Furthermore, since data can be retained for a long time, the refresh rate can be reduced.

In the case where the semiconductor device described in an embodiment below is used for the memory cell 1611, the memory cell 1612, the memory cell 1613, and the memory cell 1614, a transistor 200 can be used as the OS transistor MO61 and the OS transistor MO62. Thus, the area occupied by each set consisting of one transistor and one capacitor in the top view can be reduced, so that the memory device of this embodiment can achieve higher integration. As a result, storage capacity per unit area of the memory device of this embodiment can be increased.

The structure described in this embodiment can be used. in combination with the structures described in the other embodiments as appropriate.

### Embodiment 5

In this embodiment, a DOSRAM will be described as an example of the memory device of one embodiment of the present invention that includes an OS transistor and a capacitor, with reference to FIG. 15 and FIG. 16. A DOSRAM (registered trademark) is an abbreviation of “Dynamic Oxide Semiconductor Random Access Memory,” which indicates a RAM including a IT (transistor) IC (capacitor) memory cell. As in the NOSRAM, an OS memory is used in the DOSRAM.

### <DOSRAM 1400>

FIG. 15 illustrates a configuration example of the DOSRAM. As illustrated in FIG. 15, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, a global bit line GBLL, and a global bit line GBLR.

### [MC-SA Array 1420]

The MC-SA array 1420 has a stacked-layer structure where the memory cell array 1422 is stacked over the sense amplifier array 1423. The global bit line GBLL and the global bit line GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1> (N is an integer greater than or equal to 2). FIG. 16(A) illustrates a configuration example of the local memory cell array 1425. The local memory cell array 1425 includes a plurality of memory cells 1445, a plurality of word lines WL, a plurality of bit lines BLL, and a plurality of bit lines BLR. In the example of FIG. 16(A), the local memory cell array 1425 has an open bit-line architecture but may have a folded bit-line architecture.

FIG. 16(B) illustrates a circuit configuration example of the memory cell 1445. The memory cell 1445 includes a transistor MW1, a capacitor CS1, a terminal B1, and a terminal B2. The transistor MW1 has a function of controlling charging and discharging of the capacitor CS1. A gate of the transistor WW1 is electrically connected to the word line WL, a first terminal thereof is electrically connected to the bit line BLL/BLR, and a second terminal thereof is electrically connected to a first terminal of the capacitor. A second terminal of the capacitor CS1 is electrically connected to the terminal B2. A constant potential (e.g., a low power supply potential) is input to the terminal B2.

In the case where the semiconductor device described in a later embodiment is used in the memory cell 1445, the transistor 200 can be used as the transistor MW1. Thus, the area occupied by each set consisting of one transistor and one capacitor in the top view can be reduced, so that the memory device of this embodiment can achieve higher integration. As a result, storage capacity per unit area of the memory device of this embodiment can be increased.

The transistor MW1 includes a second gate, and the second gate is electrically connected to the terminal B1. This makes it possible to change Vₜₕ of the transistor MW1 with the potential of the terminal B1. For example, the potential of the terminal B1 is a fixed voltage (e.g., a negative constant voltage); alternatively, the potential of the terminal B1 may be changed in response to the operation of the DOSRAM 1400.

The second gate of the transistor MW1 may be electrically connected to the gate, the source, or the drain of the transistor MW1. Alternatively, the second gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a potential difference between the bit line pair, and a function of retaining the potential difference. The switch array 1444 has a function of selecting a bit line pair and bringing electrical continuity between the selected bit line pair and a global bit line pair.

Here, a bit line pair refers to two bit lines which are compared by a sense amplifier at the same time. A global bit line pair refers to two global bit lines which are compared by a global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### [Controller 1405]

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### [Row Circuit 1410]

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. With the selection signal from the column selector 1413, the switch array 1444 of each local sense amplifier array 1426 is controlled. With the control signals from the sense amplifier driver circuit 1414, the plurality of local sense amplifier arrays 1426 are independently driven.

### [Column Circuit 1415]

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a potential difference between the global bit line pair (GBLL, GBLR) and a function of retaining the potential difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data and retains the amplified data. In the specified local memory cell array 1425, the word line WL of a target row is selected by the row circuit 1410, and the data retained at the local sense amplifier array 1426 is written to the memory cell 1445 of the selected row

The read operation of the DOSRAM 1400 is briefly described. One row of the local memory cell array 1425 is specified by an address signal. In the specified local memory cell array 1425, the word line WL of a target row is in a selected state, and data of the memory cell 1445 is written to the hit line. The local sense amplifier array 1426 detects a potential difference between the bit line pair of each column as data, and retains the data. Among the data retained at the local sense amplifier array 1426, the data of a column specified by the address signal is written to the global bit line pair by the switch array 1444. The global sense amplifier array 1416 detects and retains the data of the global bit line pair. The data retained in the global sense amplifier array 1416 is output to the input/output circuit 1417. In this way, the read operation is completed.

There is theoretically no limitation on the number of rewriting operations of the DOSRAM 1400 because data is rewritten by charging and discharging of the capacitor CS1, and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM using a Si transistor. This allows less frequent refresh, which can reduce the power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, which enables a reduction in power consumption.

The structure described in this embodiment can be used in combination with the structures described in the other embodiments as appropriate.

### Embodiment 6

In this embodiment, a structure example of the OS transistor described in the above embodiments will be described with reference to FIG. 17.

### <Structure of Semiconductor Device>

An example of a semiconductor device including the transistor 200 of one embodiment of the present invention is described below. FIG. 17(A), FIG. 17(B), and FIG. 17(C) are a top view and cross-sectional views of the transistor 200 of one embodiment of the present invention and a periphery of the transistor 200. FIG. 17(A) is the top view; FIG. 17(B) is the cross-sectional view taken along the dashed-dotted line L1-L2 in FIG. 17(A), and FIG. 17(C) is the cross-sectional view taken along the dashed-dotted line W1-W2 in FIG. 17(A). Note that for simplification of the drawing, some components are not illustrated in the top view of FIG. 17(A).

The semiconductor device of one embodiment of the present invention includes the transistor 200 and an insulator 210, an insulator 212, an insulator 214, an insulator 216, an insulator 280, an insulator 282, and an insulator 284 functioning as interlayer films.

The semiconductor device also includes a conductor 246a and a conductor 246b that are electrically connected to the transistor 200 and function as plugs. The semiconductor device further includes a conductor 203 which is electrically connected to the transistor 200 and functions as a wiring.

The transistor 200 includes a conductor 260 (a conductor 260a and a conductor 260b) functioning as a first gate (also called top gate) electrode, a conductor 205 (a conductor 205a and a conductor 205b) functioning as a second gate (also called bottom gate) electrode, an insulator 250 functioning as a first gate insulator, an insulator 220, an insulator 222, and an insulator 224 functioning as second gate insulators, an oxide 230 (an oxide 230a, an oxide 230b, and an oxide 230c) including a region where a channel is formed, a conductor 240a functioning as one of a source and a drain, a conductor 240b functioning as the other of the source and the drain, and an insulator 274.

In the transistor 200, a metal oxide that will be described later can be used for the oxide 230. Using the metal oxide for the oxide 230 can inhibit generation of oxygen vacancies in the oxide 230. Thus, a transistor having high reliability can be provided. In addition, the carrier concentration in the transistor can be adjusted, whereby the degree of freedom for design is increased. Moreover, the metal oxide can be deposited by a sputtering method or the like, and thus can be used for a transistor included in a highly integrated semiconductor device.

The structure of the semiconductor device including the transistor 200 of one embodiment of the present invention will be described in detail below

The insulator 210 and the insulator 212 function as interlayer films.

As the interlayer films, a single layer or a stacked layer of an insulator such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (BaSr)TiO₃ (BST) can be used. Alternatively, to these insulators, aluminum oxide, bismuth oxide, germanium oxide, niobium oxide, silicon oxide, titanium oxide, tungsten oxide, yttrium oxide, or zirconium oxide may be added, for example. Alternatively, these insulators may be subjected to nitriding treatment. Silicon oxide, silicon oxynitride, or silicon nitride may be stacked over the insulator given above.

For example, the insulator 210 preferably functions as a barrier film that inhibits impurities such as water and hydrogen from entering the transistor 200 from a substrate side. Accordingly, for the insulator 210, it is preferable to use an insulating material having a function of inhibiting diffusion of impurities such as a hydrogen atom, a hydrogen molecule, a water molecule, and a copper atom (through which the above impurities are less likely to pass). Alternatively, it is preferable to use an insulating material having a function of inhibiting diffusion of oxygen (e.g., at least one of oxygen atoms, oxygen molecules, and the like) (through which the above oxygen is less likely to pass). For example, aluminum oxide, silicon nitride, or the like may be used for the insulator 210. With this structure, impurities such as water and hydrogen can be inhibited from diffusing into the transistor 200 side from the side closer to the substrate than the insulator 210.

For example, the dielectric constant of the insulator 212 is preferably lower than that of the insulator 210. When a material with a low dielectric constant is used for the interlayer film, the parasitic capacitance generated between wirings can be reduced.

The conductor 203 is formed to be embedded in the insulator 212, The level of the top surface of the conductor 203 and the level of the top surface of the insulator 212 can be substantially the same. Note that although a structure in whiCh the conductor 203 is a single layer is illustrated, the present invention is not limited thereto. For example, the conductor 203 may have a multilayer film structure of two or more layers. Note that in the case where a structure body has a stacked-layer structure, the layers may be distinguished by ordinal numbers corresponding to the formation order. Note that for the conductor 203, a conductive material that has high conductivity and contains tungsten, copper, or aluminum as its main component is preferably used.

In the transistor 200, the conductor 260 functions as a first gate electrode in some cases. The conductor 205 functions as a second gate electrode in some cases. In that case, by changing a potential applied to the conductor 205 not in synchronization with but independently of a potential applied to the conductor 260, the threshold voltage of the transistor 200 can be controlled. In particular, by applying a negative potential to the conductor 205, the threshold voltage of the transistor 200 can be higher, and the off-state current can be reduced. Thus, a drain current when a potential applied to the conductor 260 is 0 V can be lower in the case where a negative potential is applied to the conductor 205 than in the case where the negative potential is not applied to the conductor 205.

For example, when the conductor 205 and the conductor 260 are provided to overlap with each other and a potential is applied to the conductor 205 and the conductor 260, an electric field generated from the conductor 260 and an electric field generated from the conductor 205 are connected, thereby covering the channel formation region formed in the oxide 230.

That is, the channel formation region can be electrically surrounded by the electric field of the conductor 260 having a function of the first gate electrode and the electric field of the conductor 205 having a function of the second gate electrode. In this specification, a transistor structure in which a channel formation region is electrically surrounded by electric fields of a first gate electrode and a second gate electrode is referred to as a surrounded channel (S-channel) structure.

Like the insulator 210 or the insulator 212, the insulator 214 and the insulator 216 function as interlayer films. For example, the insulator 214 preferably functions as a barrier film that inhibits impurities such as water and hydrogen from entering the transistor 200 from the substrate side. With this structure, impurities such as water and hydrogen can be inhibited from diffusing into the transistor 200 side from the side closer to the substrate than the insulator 214. In addition, the dielectric constant of the insulator 216 is preferably lower than that of the insulator 214, for example. When a material having a low dielectric constant is used for the interlayer film, the parasitic capacitance generated between wirings can be reduced.

In the conductor 205 functioning as the second gate electrode, the conductor 205a is formed in contact with an inner wall of an opening in the insulator 214 and the insulator 216, and the conductor 205b is formed more inward. Here, the top surfaces of the conductor 205a and the conductor 205b and the top surface of the insulator 216 can be substantially level with each other. Although the transistor 200 having a structure in which the conductor 205a and the conductor 205b are stacked is illustrated, the present invention is not limited thereto. For example, the conductor 205 may have a single-layer structure or a stacked-layer structure of three or more layers.

The conductor 205a is preferably formed using a conductive material which has a function of inhibiting diffusion of impurities such as a hydrogen atom, a hydrogen molecule, a water molecule, and a copper atom (through which the above impurities are less likely to pass) Alternatively, it is preferable to use a conductive material having a function of inhibiting diffusion of oxygen (e.g., at least one of oxygen atoms, oxygen molecules, and the like) (through which the above oxygen is less likely to pass). Note that in this specification, a function of inhibiting diffusion of impurities or oxygen means a function of inhibiting diffusion of any one or all of the above impurities and the above oxygen.

For example, when the conductor 205a has a function of inhibiting diffusion of oxygen, the conductor 2056 can be inhibited from being oxidized and having reduced conductivity.

In the case where the conductor 205 also functions as a wiring, a conductive material that has high conductivity and contains tungsten, copper, or aluminum as its main component is preferably used for the conductor 205b. In that case, the conductor 203 is not necessarily provided. Note that the conductor 205b is a single layer in the drawing but may have a stacked-layer structure; for example, a stacked layer of titanium or titanium nitride and the above conductive material may be employed.

The insulator 220, the insulator 222, and the insulator 224 have a function of a second gate insulator.

The insulator 222 preferably has a barrier property. The insulator 222 having a barrier property functions as a layer that inhibits entry of impurities such as hydrogen to the transistor 200 from the peripheral portion of the transistor 200.

For example, a single layer or a stacked layer of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) is preferably used for the insulator 222. With miniaturization and high integration of a transistor, a problem of a leakage current or the like may arise because of a thinner gate insulator. When a high-k material is used for an insulator functioning as the gate insulator, a gate potential during operation of the transistor can be reduced while the physical film thickness of the gate insulator is kept.

For example, it is preferable that the insulator 220 be thermally stable. For example, silicon oxide and silicon oxynitride, which have thermal stability, are preferable. When an insulator which is a high-k material is combined with silicon oxide or silicon oxynitride, the insulator 220 having a stacked-layer structure that has thermal stability and a high dielectric constant can be obtained.

The second gate insulator may be a single layer or have a stacked-layer structure of two or more layers, although a three-layer structure is illustrated in FIG. 17, in that case, without limitation to a stacked-layer structure formed of the same material, a stacked-layer structure formed of different materials may be employed.

The oxide 230 having a region functioning as the channel formation region includes the oxide 230a, the oxide 230b over the oxide 230a, and the oxide 230c over the oxide 230b. When the oxide 230a is provided below the oxide 230b, impurities can be inhibited from diffusing into the oxide 230b from the components formed below the oxide 230a. When the oxide 230c is provided over the oxide 230b, impurities can be inhibited from diffusing into the oxide 230b from the components formed above the oxide 230c.

In addition, the semiconductor device illustrated in FIG. 17 includes a region where the conductor 240a or the conductor 240b, the oxide 230c, the insulator 250, and the conductor 260 overlap with each other. With this structure, a transistor having a high on-state current can be provided. Alternatively, a transistor having high controllability can be provided.

One of the conductor 240a and the conductor 240b functions as a source electrode and the other functions as a drain electrode.

A metal such as aluminum, titanium, chromium, nickel, copper, yttrium, zirconium, molybdenum, silver, tantalum, or tungsten or an alloy containing this as the main component can be used for the conductor 240a and the conductor 240b. In particular, a metal nitride film such as a tantalum nitride film is preferable because it has a barrier property against hydrogen or oxygen and its oxidation resistance is high.

Although FIG. 17 illustrates the conductor 240a and the conductor 240h each having a single-layer structure, the conductor 240a and the conductor 240b may have a stacked-layer structure of two or more layers. For example, a tantalum nitride film and a tungsten film may be stacked. A titanium film and an aluminum film may be stacked. A two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure in which a titanium film or a titanium nitride film, an aluminum film. or a copper film, and a titanium film. or a titanium nitride film are stacked in this order and a three-layer structure in which a molybdenum film or a molybdenum nitride film, an aluminum film or a copper film, and a molybdenum film or a molybdenum nitride film are stacked in this order. Note that a transparent conductive material containing indium oxide, tin oxide, or zinc oxide may be used.

In addition, a barrier layer may be provided over the conductor 240a and the conductor 240b. A substance having a barrier property against oxygen or hydrogen is preferably used for the barrier layer. With this structure, the conductor 240a and the conductor 240b can be inhibited from being oxidized when the insulator 274 is deposited.

For example, a metal oxide can be used for the above barrier layer. In particular, an insulating film having a barrier property against oxygen or hydrogen, such as an aluminum oxide film, a hafnium oxide film, or a gallium oxide film, is preferably used. Alternatively, silicon nitride formed by a CVD method may be used.

When the above barrier layer is included, the range of choices for the materials of the conductor 240a and the conductor 240b can be expanded. For example, a material having low oxidation resistance and high conductivity, such as tungsten or aluminum, can be used for the conductor 240a and the conductor 2408. For example, a conductor that can be easily deposited or processed can be used.

The insulator 250 functions as the first gate insulator. With miniaturization and high integration of a transistor, a problem of a leakage current or the like may arise because of a thinner gate insulator. In that case, the insulator 250 may have a stacked-layer structure like the second gate insulator. When the insulator functioning as a gate insulator has a stacked-layer structure of a high-k material and a thermally stable material, a gate potential during operation of the transistor can be reduced while the physical film thickness of the gate insulator is kept. Furthermore, the stacked-layer structure can be thermally stable and have a high dielectric constant.

The conductor 260 functioning as the first gate electrode includes the conductor 260a and the conductor 260b over the conductor 260a. Like the conductor 205a, the conductor 260a is preferably formed using a conductive material having a function of inhibiting diffusion of impurities such as a hydrogen atom, a hydrogen molecule, a water molecule, and a copper atom. Alternatively, it is preferable to use a conductive material having a function of inhibiting diffusion of oxygen (e.g., at least one of oxygen atoms, oxygen molecules, and the like).

When the conductor 260a has a function of inhibiting diffusion of oxygen, the range of choices for the material of the conductor 260b can be expanded. That is, when the conductor 260a is included, oxidization of the conductor 260b is inhibited, whereby a decrease in conductivity can be prevented.

As a conductive material which has a function of inhibiting diffusion of oxygen, for example, tantalum, tantalum nitride, ruthenium, ruthenium oxide, or the like is preferably used. The oxide semiconductor that can be used for the oxide 230 can be used for the conductor 260a. In that case, when the conductor 260b is deposited by a sputtering method, the electric resistance value of the conductor 260a can be reduced so that it can become a conductor. This can be referred to as an oxide conductor (OC) electrode.

The conductor 260 functions as a wiring and thus is preferably a conductor having high conductivity. For example, a conductive material containing tungsten, copper, or aluminum as its main component can be used for the conductor 260b. The conductor 260b may have a stacked-layer structure; for example, a stacked layer of titanium or titanium nitride and the above conductive material may be employed.

The insulator 274 is preferably provided to cover the top surface and the side surface of the conductor 260, the side surface of the insulator 250, and the side surface of the oxide 230c. Note that the insulator 274 is preferably formed using an insulating material having a function of inhibiting diffusion of impurities such as water and hydrogen and oxygen. For example, aluminum oxide, hafnium oxide, or the like is preferably used. Alternatively, for example, a metal oxide such as magnesium oxide, gallium oxide, germanium oxide, yttrium oxide, zirconium oxide, lanthanum oxide, neodymium oxide, or tantalum oxide, silicon nitride oxide, silicon nitride, or the like can be used.

By provision of the insulator 274. oxidation of the conductor 260 can be inhibited. Moreover, when the insulator 274 is included, diffusion of impurities such as water and hydrogen included in the insulator 280 into the transistor 200 can be inhibited.

The insulator 280, the insulator 282, and the insulator 284 function as interlayer

Like the insulator 214 and the insulator 274, the insulator 282 preferably functions as a barrier insulating film that inhibits impurities such as water and hydrogen from entering the transistor 200 from the outside.

Like the insulator 216, the insulator 280 and the insulator 284 preferably have a lower dielectric constant than the insulator 282. When a material having a low dielectric constant is used for the interlayer film, the parasitic capacitance generated between wirings can be reduced.

In addition, the transistor 200 may be electrically connected to another component through the plug or the wiring such as the conductor 246a and the conductor 246b embedded in the insulator 280, the insulator 282, and the insulator 284.

As a material of the conductor 246a and the conductor 246b, a single layer or a stacked layer of a conductive material such as a metal material, an alloy material, a metal nitride material, or a metal oxide material can be used as in the conductor 205. For example, it is preferable to use a high-melting-point material that has both heat resistance and conductivity, such as tungsten or molybdenum. Alternatively, it is preferable to use a low-resistance conductive material such as aluminum or copper. The use of a low-resistance conductive material can reduce wiring resistance.

For example, the conductor 246a and the conductor 246b employ a stacked-layer structure of tantalum nitride or the like, whiCh is a conductor having a barrier property against hydrogen and oxygen, and tungsten, which has high conductivity, whereby the diffusion of impurities from the outside can be inhibited while the conductivity of a wiring is kept.

In addition, an insulator 276a and an insulator 276b having a barrier property may be placed between the conductor 246a and the conductor 246b, and the insulator 280. Providing the insulator 276a and the insulator 276b can inhibit oxygen in the insulator 280 from reacting with the conductor 246a and the conductor 246b and oxidizing the conductor 246a and the conductor 246b.

Furthermore, by provision of the insulator 276a and the insulator 276b having a barrier property, the range of choices for the materials of the conductor used for the plug or the wiring can be expanded. The use of a metal material having an oxygen absorbing property and high conductivity for the conductor 246a and the conductor 246b, for example, can provide a semiconductor device with low power consumption. Specifically, a material having low oxidation resistance and high conductivity, such as tungsten or aluminum, can be used. For example, a conductor that can be easily deposited or processed can be used.

With the above structure, a semiconductor device that includes a transistor including an oxide semiconductor and having a high on-state current can be provided. Alternatively, a semiconductor device that includes a transistor including an oxide semiconductor and having a low off-state current can be provided. Alternatively, a semiconductor device that has a small variation in electrical characteristics, stable electrical characteristics, and improved reliability can be provided.

### <Metal Oxide>

As the oxide 230, a metal oxide functioning as an oxide semiconductor is preferably used. A metal oxide that can be used for the oxide 230 of the present invention will be described below

The metal oxide preferably contains at least indium or zinc. In particular, indium and zinc are preferably contained. Furthermore, aluminum, gallium, yttrium, tin, or the like is preferably contained in addition to them. Furthermore, one or a plurality of kinds selected from boron, titanium, iron, nickel, germanium, zirconium, molybdenum, lanthanum, cerium, neodymium, hafnium, tantalum, tungsten, magnesium, and the like may be contained.

Here, the case where the metal oxide is an In-M-Zn oxide containing indium, an element M, and zinc is considered. Note that the element M is aluminum, gallium, yttrium, tin, or the like. Other elements that can be used as the element M include boron, titanium, iron, nickel, germanium, zirconium, molybdenum, lanthanum, cerium, neodymium, hafnium, tantalum, tungsten, and magnesium. Note that a plurality of the above-described elements may be used in combination as the element M in some cases.

### [Structure of Metal Oxide]

Oxide semiconductors (metal oxides) can be classified into a single crystal oxide semiconductor and a non-single-crystal oxide semiconductor. Examples of the non-single-crystal oxide semiconductors include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in sonic cases. Note that a clear crystal grain boundary (also referred to as grain boundary) is difficult to observe even in the vicinity of distortion in the CAAC-OS. That is, formation of a crystal grain boundary is inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, an In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer,

The CAAC-OS is a metal oxide with high crystallinity. By contrast, in the CAAC-OS, a reduction in electron mobility due to the crystal grain boundary is less likely to occur because it is difficult to observe a clear crystal grain boundary. Furthermore, entry of impurities, formation of defects, or the like might decrease the crystallinity of a metal oxide, which means that the CAAC-OS is a metal oxide having small amounts of impurities and defects (e.g., oxygen vacancies (also referred to as V_{O})). Thus, a metal oxide including a CAAC-OS is physically stable. Therefore, the metal oxide including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement Furthermore, there is no regularity of crystal orientation between different nanocrystals in the nc-OS. Thus, the orientation in the Whole film is not observed. Accordingly, in some cases, the nc-OS cannot be distinguished from an a-like OS or an amorphous oxide semiconductor, depending on the analysis method.

Note that indium-gallium-zinc oxide (hereinafter referred to as IGZO) that is a kind of metal oxide containing indium, gallium, and zinc has a stable structure in some cases by being formed of the above-described nanocrystals. In some cases, IGZO has a stable structure when formed of smaller crystals (e.g., the above-described nanocrystals) rather than larger crystals (here, crystals with a size of several millimeters or several centimeters) because crystal growth tends to hardly occur particularly in the air.

An a-like OS is a metal oxide having a structure between those of the nc-OS and an amorphous oxide semiconductor. The a-like OS contains a void or a low-density region. That is, the a-like OS has low crystallinity as compared with the nc-OS and the CAAC-OS,

The oxide semiconductor (metal oxide) can have various structures which show different properties. Two or more kinds of the amorphous oxide semiconductor, the polycrystalline oxide semiconductor, the a-like OS, the nc-OS, and the CAAC-OS may be included in the oxide semiconductor of one embodiment of the present invention.

### [Impurities]

Here, the influence of each impurity in the metal oxide will be described.

When the metal oxide contains an alkali metal or an alkaline earth metal, defect states are formed and carriers are generated, in some cases. Thus, a transistor using a metal oxide that contains an alkali metal or an alkaline earth metal in its channel formation region is likely to have normally-on characteristics. Therefore, it is preferable to reduce the concentration of an alkali metal or an alkaline earth metal in the metal oxide. Specifically, the concentration of an alkali metal or an alkaline earth metal in the metal oxide obtained by secondary ion mass spectrometry (SIMS) is set lower than or equal to 1×10¹⁸ atoms/cm³, preferably lower than or equal to 2×10¹⁶ atoms/cm³.

Hydrogen contained in a metal oxide reacts with oxygen bonded to a metal atom to become water, and thus forms an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron which is a carrier. Thus, a transistor using a metal oxide containing hydrogen is likely to have normally-on characteristics.

Accordingly, hydrogen in the metal oxide is preferably reduced as much as possible. Specifically, the hydrogen concentration of the metal oxide, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When a metal oxide in which impurities are sufficiently reduced is used in a channel formation region of a transistor, stable electrical characteristics can be given.

The structure, method, and the like described above in this embodiment can be used in combination as appropriate with the structures, methods, and the like described in the other embodiments.

### REFERENCE NUMERALS

200: transistor,
203: conductor,
205: conductor,
205a: conductor,
205b: conductor,
210: insulator,
212: insulator,
214: insulator,
216: insulator,
220: insulator,
222: insulator,
224: insulator,
230: oxide,
230a: oxide,
230b: oxide,
230c: oxide,
240a: conductor,
240b: conductor,
246a: conductor,
246b: conductor,
250: insulator,
260: conductor,
260a: conductor,
260b: conductor,
274: insulator,
276a: insulator,
276b: insulator,
280: insulator,
282: insulator,
284: insulator,
600: plasma CVD apparatus,
601: various kinds of deposition conditions,
602: various kinds of deposition conditions,
602A: gas,
602B: pressure,
602C: deposition power,
602D: distance between electrodes,
602E: temperature,
603: measurement value,
603B: output value,
604: various kinds of deposition conditions,
611: control device,
612: treatment chamber,
613: arithmetic portion,
614: controller IC,
615: deposition condition input means,
616: gas supply means,
617: evacuation means,
618: electric power supply means,
619: electrode interval adjustment means,
620: temperature adjustment means,
621: matching box,

### 1400: DOSRAM,

1405: controller,
1410: row circuit,
1411: decoder,
1412: word line driver circuit,
1413: column selector,
1414: sense amplifier driver circuit,
1415: column circuit,
1416: global sense amplifier array,
1417: input/output circuit,
1420: MC-SA array,
1422: memory cell array,
1423: sense amplifier array,
1425: local memory cell array,
1426: local sense amplifier array,
1444: switch array,
1445: memory cell,
1446: sense amplifier,
1447: global sense amplifier,

### 1600: NOSRAM,

1610: memory cell array,
1611: memory cell,
1612: memory cell,
1613: memory cell,
1614: memory cell,
1640: controller,
1650: row driver,
1651: row decoder,
1652: word line driver,
1660: column driver,
1661: column decoder,
1662: driver,

### 1663: DAC,

1670: output driver,
1671: selector,

### 1672: ADC,

1673: output buffer,
4000: apparatus,
4010: atmosphere-side substrate supply chamber,
4012: atmosphere-side substrate transfer chamber,
4014: cassette port,
4016: alignment port,
4018: transfer robot,
4020a: load lock chamber,
4020b: unload lock chamber,
4024a: treatment chamber,
4024b: treatment chamber,
4026: transfer robot,
4028: gate valve,
4029: transfer chamber,
4030a: transport, chamber,
4030b: transport chamber,
4034a: treatment chamber,
4034b: treatment chamber,
4034c: treatment chamber,
4034d: treatment chamber,
4034e: treatment chamber,
4036: transfer robot,
4038: gate valve,
4039: transfer chamber

1. A thin film manufacturing apparatus comprising a treatment chamber, a gas supply part, an evacuation part, an electric power supply part, an arithmetic portion, and a control device,
wherein the gas supply part is configured to supply gas into the treatment chamber,
wherein the evacuation part is configured to adjust a pressure in the treatment chamber,
wherein the electric power supply part is configured to apply voltage between electrodes provided in the treatment chamber,
wherein the arithmetic portion is configured to perform detection of an abnormal state and inference by using a neural network during thin film formation, and
wherein the control device is configured to control one or more set conditions in accordance with results of the detection and the inference during the thin film formation.

2. A thin film manufacturing apparatus comprising a treatment chamber, a gas supply part, an evacuation part, an electric power supply part, a matching box, an arithmetic portion, and a control device,
wherein the gas supply part is configured to supply gas into the treatment chamber,
wherein the evacuation part is configured to adjust a pressure in the treatment chamber,
wherein the electric power supply part is configured to apply voltage between electrodes provided in the treatment chamber using a high-frequency power source,
wherein the matching box is configured to induce AC power effectively and to acquire data during thin film formation,
wherein the arithmetic portion is configured to perform detection of an abnormal state and inference by using a neural network during the thin film formation, and
wherein the control device is configured to control one or more set conditions in accordance with results of the detection and the inference during the thin film formation.

3. A thin film manufacturing apparatus comprising a treatment chamber, a gas supply part, an evacuation part, an electric power supply part, a matching box, an electrode interval adjustment part, a temperature adjustment part, an arithmetic portion, and a control device,
wherein the gas supply part is configured to supply gas into the treatment chamber,
wherein the evacuation part is configured to adjust a pressure in the treatment chamber,
wherein the electric power supply part is configured to apply voltage between two electrodes provided in the treatment chamber using a high-frequency power source,
wherein the matching box part is configured to induce AC power effectively and to acquire data during thin film formation,
wherein the electrode interval adjustment part is configured to adjust an interval between the two electrodes provided in the treatment chamber,
wherein the temperature adjustment part is configured to adjust a temperature in the treatment chamber,
wherein the arithmetic portion is configured to perform detection of an abnormal state and inference by using a neural network during the thin film formation, and
wherein the control device is configured to control one or more set conditions in accordance with results of the detection and the inference during the thin film formation.

4. The thin film manufacturing apparatus according to claim 3,
wherein the neural network is configured to finish learning for performing the detection and learning for performing the inference in advance based on the one or more set conditions accumulated in a certain period and the data acquired during the thin film formation under the one or more set conditions.

5. The thin film manufacturing apparatus according to claim 1,
wherein the arithmetic portion comprises a memory,
wherein the memory comprises a transistor and a capacitor, and
wherein the transistor comprises a metal oxide in a channel formation region.

6. The thin film manufacturing apparatus according to claim 1,
wherein the arithmetic portion comprises a semiconductor device,
wherein the semiconductor device is configured to perform operation of the neural network,
wherein the semiconductor device comprises a memory cell, and
wherein a transistor comprising a metal oxide in a channel formation region is used in the memory cell.

7. The thin film manufacturing apparatus according to claim 2,
wherein the one or more set conditions are selected from a kind and a flow rate or a flow rate ratio of the gas, the pressure in the treatment chamber, the voltage applied between the electrodes, a distance between the electrodes, and a substrate temperature, and
wherein the data is one or both of a difference between a maximum voltage and a minimum voltage of AC voltage and a potential difference between a coil and an earth.

8. The thin film manufacturing apparatus according to claim 2,
wherein a deposition treatment using a plasma CVD method is performed in the treatment chamber.

9. The thin film manufacturing apparatus according to claim 2,
wherein the neural network is configured to finish learning for performing the detection and learning for performing the inference in advance based on the one or more set conditions accumulated in a certain period and the data acquired during the thin film formation under the one or more set conditions.

10. The thin film manufacturing apparatus according to claim 2,
wherein the arithmetic portion comprises a memory,
wherein the memory comprises a transistor and a capacitor, and
wherein the transistor comprises a metal oxide in a channel formation region.

11. The thin film manufacturing apparatus according to claim 2,
wherein the arithmetic portion comprises a semiconductor device,
wherein the semiconductor device is configured to perform operation of the neural network,
wherein the semiconductor device comprises a memory cell, and
wherein a transistor comprising a metal oxide in a channel formation region is used in the memory cell.

12. The thin film manufacturing apparatus according to claim 3,
wherein the one or more set conditions are selected from a kind and a flow rate or a flow rate ratio of the gas, the pressure in the treatment chamber, the voltage applied between the electrodes, a distance between the electrodes, and a substrate temperature, and
wherein the data is one or both of a difference between a maximum voltage and a minimum voltage of AC voltage and a potential difference between a coil and an earth.

13. The thin film manufacturing apparatus according to claim 3,
wherein a deposition treatment using a plasma CVD method is performed in the treatment chamber.

14. The thin film manufacturing apparatus according to claim 3,
wherein the neural network is configured to finish learning for performing the detection and learning for performing the inference in advance based on the one or more set conditions accumulated in a certain period and the data acquired during the thin film formation under the one or more set conditions.

15. The thin film manufacturing apparatus according to claim 3,
wherein the arithmetic portion comprises a memory,
wherein the memory comprises a transistor and a capacitor, and
wherein the transistor comprises a metal oxide in a channel formation region.

16. The thin film manufacturing apparatus according to claim 3,
wherein the arithmetic portion comprises a semiconductor device,
wherein the semiconductor device is configured to perform operation of the neural network,
wherein the semiconductor device comprises a memory cell, and
wherein a transistor comprising a metal oxide in a channel formation region is used in the memory cell.
